(19) United States
(12) Patent Application Publication
(10) Pub. No.: US 2025/0040279 A1
(43) Pub. Date: Jan. 30, 2025

(54) IMAGE SENSOR

(71) Applicant: Samsung Electronics Co., Ltd., Suwon-si (KR)

(72) Inventors: Minkwan KIM, Suwon-si (KR); Jongwoo HONG, Suwon-si (KR); Jonghyun GO, Suwon-si (KR); Haneul KIM, Suwon-si (KR); Chang Kyu LEE, Suwon-si (KR); Keun Yeong CHO, Suwon-si (KR); Joonhyuk HWANG, Suwon-si (KR)

(73) Assignee: Samsung Electronics Co., Ltd., Suwon-si (KR)

(21) Appl. No.: 18/589,834

(22) Filed: Feb. 28, 2024

(30) Foreign Application Priority Data
Jul. 26, 2023 (KR) 10-2023-0097811

(51) Int. Cl. H01L 27/146

(52) U.S. Cl. CPC H01L 27/14627; H01L 27/14621; H01L 27/14645; H01L 27/14685

(57) ABSTRACT

An image sensor includes a pixel array in which pixels having photoelectric conversion elements are arranged in a matrix, color filters corresponding to the pixels and configured to selectively transmit light of at least two different wavelength bands, and microlenses on the color filters. At least some of the microlenses may have different shapes depending on respective wavelength bands that respective corresponding color filters at least partially overlapping with the at least some microlenses are configured to selectively transmit, such that the at least some microlenses are configured to compensate for chromatic aberration between the lights passing through the respective corresponding color filters.

### CROSS-REFERENCE TO RELATED APPLICATION

This U.S. non-provisional application claims priority under 35 USC § 119 to Korean Patent Application No. 10-2023-0097811, filed on Jul. 26, 2023, in the Korean Intellectual Property Office, the disclosure of which is herein incorporated by reference in its entirety.

### BACKGROUND

Example embodiments relate to image sensors.

An image sensor is a semiconductor-based sensor receiving light and generating an electrical signal, and includes a pixel array including a plurality of pixels.

In an image sensor, pixels for autofocusing may be included in a pixel array to allow a user to focus on a subject to be captured. A technology such as phase detection autofocusing (PDAF) has been developed to implement such autofocusing. The PDAF is a technology for implementing autofocusing using a phase difference occurring in adjacent pixels.

However, in the case of PDAF technology, a ratio of light entering two adjacent pixels may vary depending on various conditions, so that autofocusing performance may be deteriorated.

### SUMMARY

Some example embodiments of the inventive concepts provide an image sensor having improved sensitivity depending on illumination conditions.

Some example embodiments provide an image sensor having improved autofocusing performance due to improved light collection efficiency depending on illumination conditions.

According to some example embodiments, an image sensor, may include a pixel array in which a plurality of pixels having photoelectric conversion elements are arranged in a matrix in a first direction and a second direction intersecting the first direction. The image sensor may include color filters corresponding to the plurality of pixels, each color filter configured to selectively transmit light of a particular wavelength band, at least some of the color filters configured to selectively transmit light of at least two different wavelength bands from each other. The image sensor may include microlenses on the color filters, each microlens of the microlenses at least partially overlapping a separate corresponding color filter of the color filters in a third direction that is perpendicular to the first and second directions, the microlenses configured to condense lights incident on the plurality of pixels and entering the photoelectric conversion elements through the color filters. At least some microlenses of the microlenses may have different shapes depending on respective wavelength bands that respective corresponding color filters at least partially overlapping with the at least some microlenses are configured to selectively transmit, such that the at least some microlenses are configured to compensate for chromatic aberration between the lights passing through the respective corresponding color filters. The pixel array may be in a pixel region, and a distance between an uppermost point of each respective microlens of the microlenses and a center of a corresponding pixel of the plurality of pixels at least partially overlapping the respective microlens in the third direction may increase in a direction toward an edge portion of the pixel region from a central portion of the pixel region.

According to some example embodiments, an image sensor may include a pixel array in which a plurality of pixels having photoelectric conversion elements are arranged in a matrix in a first direction and a second direction intersecting the first direction. The image sensor may include first to third color filters corresponding to the plurality of pixels, the first to third color filters configured to transmit light of sequentially longer wavelengths, such that the second color filter is configured to selectively transmit a longer wavelength than the first color filter, and the third color filter is configured to selectively transmit a longer wavelength than the second color filter. The image sensor may include first to third microlenses, respectively on the first to third color filters, the first to third microlenses configured to condense lights incident on the pixels through the first to third color filters. Each microlens of the first to third microlenses, when viewed in a cross-section passing through a center of a corresponding pixel and taken in a direction parallel to the first direction, may have an asymmetric shape with respect to a line passing through the center of the corresponding pixel. Each microlens of the first to third microlenses may have a respective uppermost point that is a point of the microlens protruding furthest in a third direction perpendicular to the first and second directions, and heights of respective uppermost points of the first to third microlenses in the third direction increase sequentially, such that a height of an uppermost point of the second microlens is greater than a height of an uppermost point of the first microlens, and a height of an uppermost point of the third microlens is greater than the height of the uppermost point of the second microlens. The pixel array may be in a pixel region, and a distance between the respective uppermost point of each microlens of the first to third microlenses and a center of a respective pixel corresponding to the microlens may increase in an outward direction toward an edge portion of the pixel region from a central portion of the pixel region.

According to some example embodiments, a method of manufacturing an image sensor, the image sensor comprising a pixel array in which a plurality of pixels having photoelectric conversion elements are arranged in a matrix in a first direction and a second direction intersecting the first direction, color filters provided to correspond to the pixels and having at least two types of different colors, and microlenses provided on the color filters to condense lights incident on the pixels through the color filters, may include forming a planarization layer on the color filters, the planarization formed of a microlens material, providing a photoresist on the planarization layer, the photoresist having an asymmetrical shape, reflowing the photoresist, and etching the planarization layer using the reflowed photoresist as a mask.

### BRIEF DESCRIPTION OF DRAWINGS

The above and other aspects, features, and advantages of the present inventive concepts will be more clearly understood from the following detailed description, taken in conjunction with the accompanying drawings.

FIG. 1 is a block diagram of an image sensor according to some example embodiments.

FIG. 2A is a diagram illustrating a pixel array including a plurality of pixels according to some example embodiments, and FIG. 2B is a circuit diagram of a pixel in an image sensor according to some example embodiments.

FIG. 3A is a plan view illustrating a portion of a pixel array according to some example embodiments, and FIG. 3B is a plan view illustrating a single pixel group in FIG. 3A according to some example embodiments.

FIGS. 4A and 4B are cross-sectional views taken along line A-A′ of FIG. 3B, respectively illustrating pixels of a first region and a second region according to some example embodiments.

FIGS. 5A and 5B are cross-sectional views illustrating portions of two adjacent pixels together with an optical path according to some example embodiments.

FIGS. 6A and 6B are cross-sectional views illustrating only microlens portions and an optical path when a shape of a microlens in the second region is changed according to some example embodiments.

FIG. 7A is a diagram illustrating a portion of microlenses according to some example embodiments and the diagram of FIG. 7A includes a cross-sectional view and a corresponding contour diagram illustrating first to third microlenses among the microlenses of FIG. 6B according to some example embodiments, and FIG. 7B includes drawings illustrating cross-sections when the first to third microlenses are cut along lines Ba-Ba′, Bb-Bb′, and Bc-Bc′ of FIG. 7A according to some example embodiments.

FIG. 8A is a diagram illustrating an example of a pixel group having an offset structure according to some example embodiments, and FIG. 8B is a cross-sectional view taken along line C-C′ of FIG. 8A according to some example embodiments.

FIG. 9 is a diagram illustrating an optical path when microlenses are manufactured in different sizes and shapes corresponding to colors and are formed in an offset structure according to some example embodiments.

FIG. 10 is a diagram illustrating a portion of microlenses according to some example embodiments, and the diagram of FIG. 10 includes a cross-sectional view and a corresponding contour diagram illustrating first to third microlenses.

FIGS. 11A and 11B are diagrams illustrating the degree of broadening for different microlens formations according to some example embodiments. FIG. 11A is a cross-sectional view illustrating a case in which a symmetrical microlens is used, and FIG. 11B is a cross-sectional view illustrating a case in which an asymmetrical microlens is used.

FIGS. 12A and 12B are cross-sectional views illustrating only optical paths of a symmetrical microlens and an asymmetrical microlens according to some example embodiments.

FIGS. 13A, 13B, and 13C and FIGS. 14A, 14B, and 14C are diagrams illustrating an optical path correction effect using a symmetrical microlens and an asymmetrical microlens when an angle of incidence of light entering a microlens having a thickness of 500 nm is 10 degrees according to some example embodiments.

FIGS. 15A, 15B, and 15C and FIGS. 16A, 16B, and 16C are diagrams illustrating an optical path correction effect using a symmetrical microlens and an asymmetrical microlens when an angle of incidence of light entering a microlens having a thickness of 500 nm is 20 degrees according to some example embodiments.

FIG. 17 is a diagram illustrating rigorous coupled-wave analysis (RCWA) images when an angle of incidence is changed to 10 degrees, 12 degrees, 14 degrees, 16 degrees, 18 degrees, and 20 degrees according to some example embodiments.

FIGS. 18A and 18B are graphs, each illustrating the intensity of light depending on a position on a pixel in FIG. 17 according to some example embodiments.

FIGS. 19A and 19B are graphs illustrating an optical path correction effect using an asymmetrical microlens when all conditions, other than a height, are the same according to some example embodiments.

FIG. 20 is a contrast graph during autofocusing when an image sensor according to the related art is used as a comparative example and an image sensor according to some example embodiments is used as an experimental example.

FIG. 21A is a diagram illustrating a pixel region in an image sensor according to some example embodiments, and FIG. 21B is a diagram sequentially illustrating shapes of microlenses depending on positions of the pixel region according to some example embodiments.

FIG. 22 is a contrast graph during autofocusing when an image sensor according to the related art is used as a comparative example and an image sensor according to some example embodiments is used as an experimental example.

FIGS. 23A, 23B, and 23C are diagrams sequentially illustrating a method of manufacturing an asymmetrical microlens according to some example embodiments.

FIGS. 24A, 24B, and 24C are diagrams illustrating a single pixel group in an image sensor according to some example embodiments.

FIG. 25 is a graph illustrating relative absorptivity of light by color depending on thickness when a substrate is a silicon-based substrate according to some example embodiments.

FIG. 26 is a diagram illustrating a pixel array of an image sensor according to some example embodiments.

FIGS. 27A and 27B are diagrams illustrating pixel arrays of an image sensor according to some example embodiments.

FIG. 28 is a diagram illustrating a pixel array of an image sensor according to some example embodiments.

FIG. 29 is a diagram illustrating a pixel array of an image sensor according to some example embodiments.

### DETAILED DESCRIPTION

The present inventive concepts may be modified in various ways, and may have various example embodiments, among which some, specific example embodiments will be described in detail with reference to the accompanying drawings. However, it should be understood that the description of the specific example embodiments of the present inventive concepts is not intended to limit the present inventive concepts to a particular mode of practice, and that the present inventive concepts are to cover all modifications, equivalents, and substitutes included in the spirit and technical scope of the present disclosure.

In order to clearly describe the present inventive concepts, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present inventive concepts are not necessarily limited to those illustrated in the drawings.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values or shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

Some example embodiments of the present inventive concepts relate to an image sensor, which is a device generating a digital signal (or an electrical signal) based on light reflected from a subject and generating digital image data based on the electrical signal. The image sensor may include, for example, a single image sensor selected from among image sensors having different attributes, such as an RGB sensor, a black and white (BW) sensor, an infrared (IR) sensor, or an ultraviolet (UV) sensor, a plurality of image sensors having the same attribute, or a plurality of image sensors having different attributes. A charge-coupled device (CCD) or a complementary metal oxide semiconductor (CMOS) are two types of image sensors.

Hereinafter, example embodiments will be described in detail with reference to the attached drawings. Like reference numerals in the drawings denote like elements, and redundant descriptions thereof will be omitted.

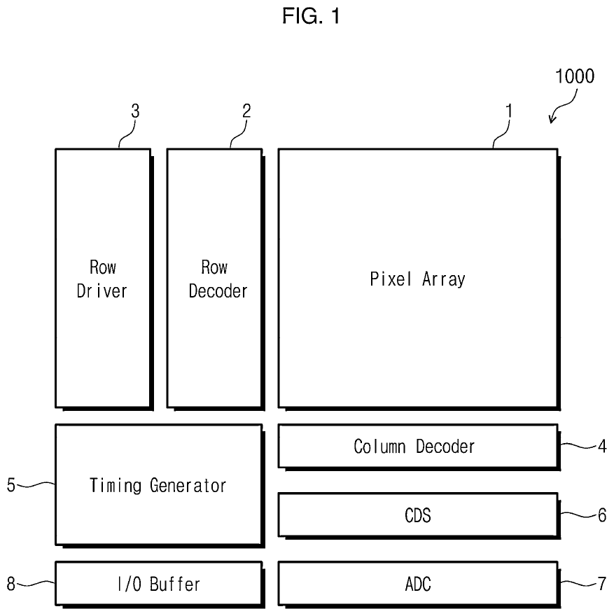

FIG. 1 is a block diagram of an image sensor according to some example embodiments.

Referring to FIG. 1, an image sensor 1000 according to some example embodiments may include a pixel array 1, a row decoder 2, a row driver 3, and a column decoder 4, a timing generator 5, a correlated double sampler (CDS) 6, an analog-to-digital converter (ADC) 7, and an input/output (I/O) buffer 8.

The pixel array 1 may include a plurality of two-dimensionally arranged pixels, and may convert an optical signal into an electrical signal. The pixel array 1 may be driven by a plurality of driving signals such as a pixel select signal, a reset signal, and a charge transfer signal from the row driver 3. The converted electrical signal may be provided to the correlated double sampler 6.

The row driver 3 may provide a plurality of driving signals to the pixel array 1 to drive a plurality of pixels based on a result decoded by the row decoder 2. When the pixels are arranged in a matrix, driving signals may be provided for each row.

The timing generator 5 may provide a timing signal and a control signal to the row decoder 2 and the column decoder 4.

The correlated double sampler 6 may receive, hold, and sample the electrical signal generated by the pixel array 1. The correlated double sampler may perform double sampling on a specific noise level and a signal level of an electrical signal to output a difference level corresponding to a difference between the noise level and the signal level.

The analog-to-digital converter 7 may convert an analog signal corresponding to the difference level, output from the correlated double sampler 6, into a digital signal and may then output the digital signal.

The input/output buffer 8 may latch digital signals, and may sequentially output the latched digital signals to an image signal processor, not illustrated, based on a result decoded by the column decoder 4.

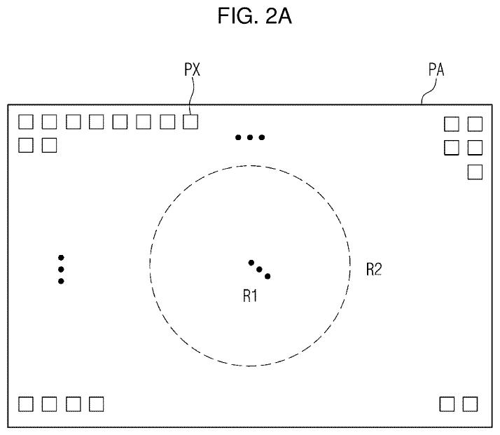

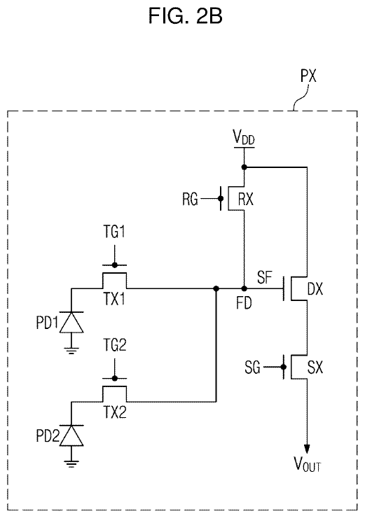

FIG. 2A is a diagram illustrating a pixel array including a plurality of pixels according to some example embodiments, and FIG. 2B is a circuit diagram of a pixel in an image sensor according to some example embodiments. In FIG. 2B, all pixels have the same or substantially the same configuration and operation in terms of circuitry. Therefore, a description of a single pixel will be provided for ease of description.

Referring to FIGS. 2A and 2B, the image sensor may include a pixel array in which a plurality of pixels are arranged. The pixel array may be provided in a pixel region PA of the image sensor.

According to some example embodiments, each pixel PX may include a first sub-pixel and a second sub-pixel. The first sub-pixel may include a first photoelectric conversion element PD1 and a first pixel circuit, and the second sub-pixel may include a second photoelectric conversion element PD2 and a second pixel circuit. The first pixel circuit may include a plurality of first semiconductor elements, and the second pixel circuit may include a plurality of second semiconductor elements.

The first pixel circuit may include a first transfer transistor TX1, a reset transistor RX, a select transistor SX, and a driving transistor DX. The second pixel circuit may include a first transfer transistor TX1, a reset transistor RX, a select transistor SX, and a driving transistor DX. As illustrated in FIG. 2, the first pixel circuit and the second pixel circuit may share the reset transistor RX, the select transistor SX, and the driving transistor DX. However, this is only an example, and example embodiments are not limited to that illustrated in FIG. 2. The first and second pixel circuits may be designed in various ways. Gate electrodes of the first and second transfer transistors TX1 and TX2, the reset transistor RX, and the select transistor SX may be connected to driving signal lines TG1, TG2, RG, and SG, respectively.

In some example embodiments, the first pixel circuit may generate a first electrical signal from a charge generated by the first photoelectric conversion element PD1 and may output the first electrical signal to a first column line, and the second pixel circuit may generate a second electrical signal from a charge generated by the second photoelectric conversion element PD2 and may output the second electrical signal to a second column line. According to some example embodiments, two or more first pixel circuits disposed adjacent to each other may share a single first column line. Similarly, two or more second pixel circuits disposed adjacent to each other may share a single second column line. Second pixel circuits disposed adjacent to each other may share a portion of the second semiconductor elements.

The first transfer transistor TX1 may be connected to the first transfer gate TG1 and the first photoelectric conversion element PD1, and the second transfer transistor TX2 may be connected to the second transfer gate TG2 and the second photoelectric conversion element PD2. The first and second transfer transistors TX1 and TX2 may share a floating diffusion region FD. The first and second photoelectric conversion elements PD1 and PD2 may generate and accumulate charges in proportion to the intensity of externally incident light. The first and second transfer transistors TX1 and TX2 may sequentially transfer the charges, accumulated in the first and second photoelectric conversion elements PD1 and PD2, to the floating diffusion region FD. Complementary signals may be applied to the first and second transfer gates TG1 and TG2 to transfer the charges, generated by one of the first or second photoelectric conversion devices PD1 or PD2, to the floating diffusion region FD. Accordingly, the floating diffusion region FD may accumulate the charges generated by one of the first or second photoelectric conversion elements PD1 or PD2.

The reset transistor RX may periodically reset the charges accumulated in the floating diffusion region FD. As an example, electrodes of the reset transistor RX may be connected to the floating diffusion region FD and a power supply voltage V_{DD}. When the reset transistor RX is turned on, the charges accumulated in the floating diffusion region FD may be discharged by a potential difference from the power supply voltage V_{DD}. Thus, the floating diffusion region FD may be reset and a voltage of the floating diffusion region FD may be the same as the power supply voltage V_{DD}.

An operation of the driving transistor DX may be controlled based on the amount of the charges accumulated in the floating diffusion region FD. The driving transistor DX may serve as a source-follower buffer amplifier in combination with a current source disposed outside the pixel PX. As an example, the driving transistor DX may amplify a potential change occurring as the charges are accumulated in the floating diffusion region FD, and may output the potential change to an output line VOUT.

The select transistor SX may select pixels PX to be read in units of rows. When the select transistor SX is turned on, an electrical signal output from the driving transistor DX may be transferred to the select transistor SX.

The image sensor according to some example embodiments may provide an autofocusing function using the first pixel signal, obtained after the first transfer transistor TX1 is turned on, and the second pixel signal obtained after the second transfer transistor TX2 is turned on. However, a pixel circuit of a pixel providing the autofocusing function is not limited to that illustrated in FIG. 2B, and some elements may be added or omitted as necessary.

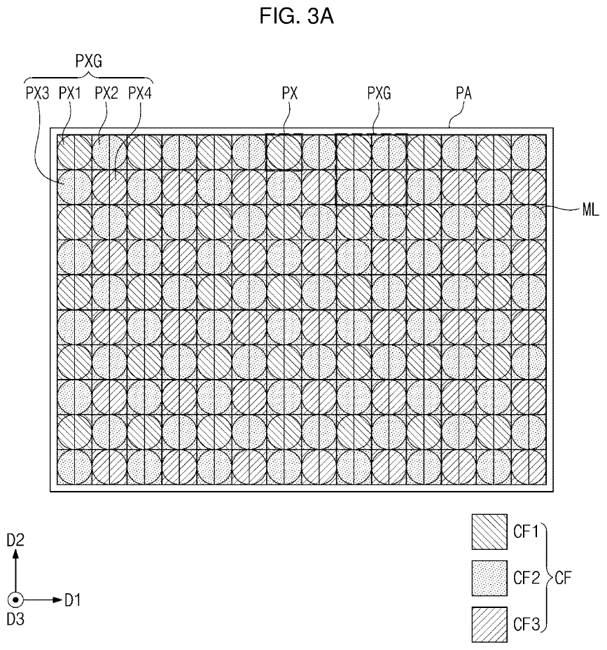

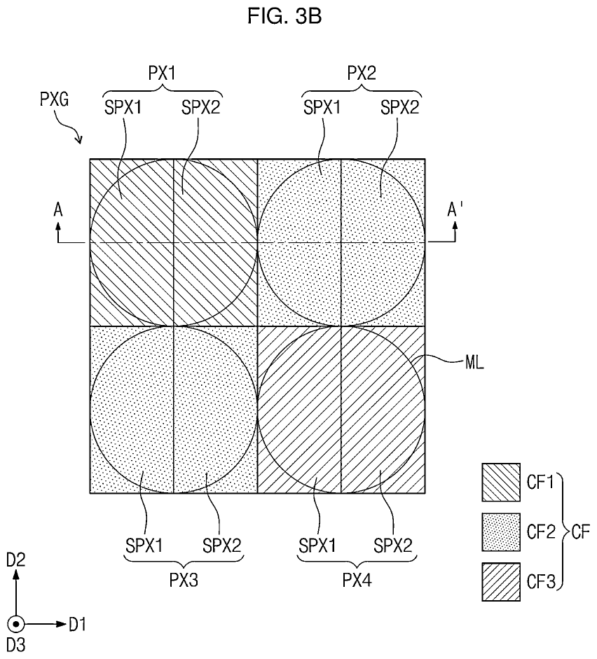

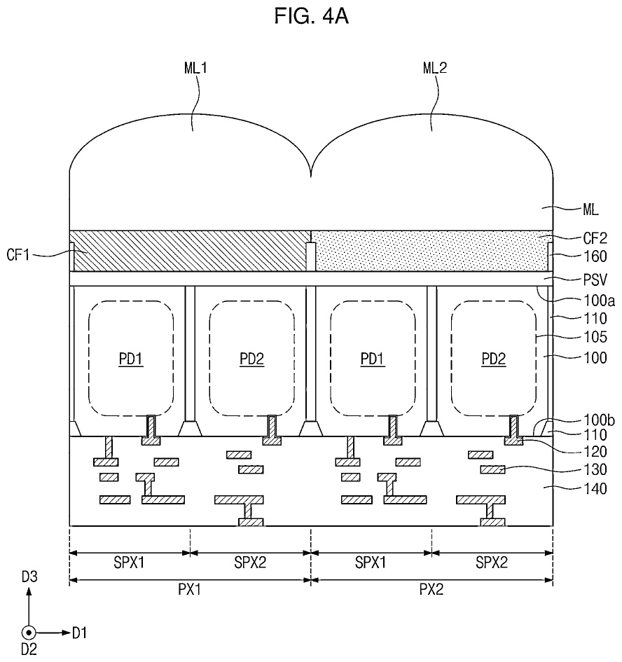

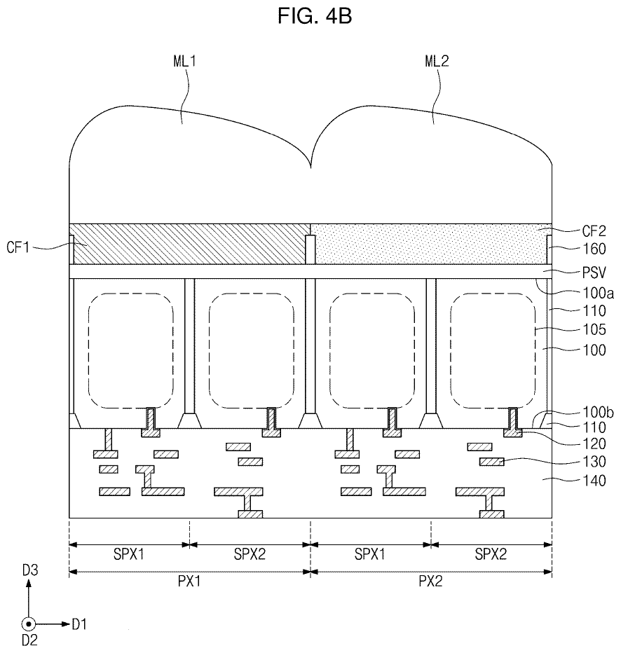

FIG. 3A is a plan view illustrating a portion of a pixel array according to some example embodiments, and FIG. 3B is a plan view illustrating the single pixel group in FIG. 3A. FIGS. 4A and 4B are cross-sectional views, taken along line A-A′ of FIG. 3B and each illustrating pixels of a first region and a second region according to some example embodiments.

According to some example embodiments, the image sensor may include a plurality of pixels PX including a plurality of photoelectric conversion elements PD (e.g., a plurality of pixels PX including respective photoelectric conversion elements PD) provided on a semiconductor substrate, color filters (CF) CF1, CF2, and CF3 provided on the photoelectric conversion elements PD (e.g., corresponding to separate, respective pixels PX) and having at least two types of different colors (e.g., configured to selectively transmit light of at least two different wavelength bands of visible light corresponding to at least two different colors), and microlenses ML provided on the color filters CF to condense light entering the photoelectric conversion elements PD through the color filters CF. Hereinafter, the image sensor will be described with reference to FIGS. 3A and 3B and FIGS. 4A and 4B.

The image sensor according to some example embodiments may have a pixel region PA provided with a pixel array including pixels PX. The pixel region PA may include a first region R1 and a second region R2. The first region R1 may correspond to a central portion, having a center, in the pixel region PA, and the second region R2 may correspond to an edge region surrounding the first region R1 within the pixel region PA, for example, an edge portion.

A pixel array, including pixels arranged in a two-dimensional matrix, may be disposed in the pixel region PA.

The pixel array may be provided with a plurality of pixel groups PXG, each including two or more, for example, four pixels PX. Each of the pixels PX may include at least one photoelectric conversion element PD. The pixels PX may be provided with microlenses ML and color filters CF.

Each of the microlenses ML may serve to refract and/or condense light. Each of the color filters CF may be disposed behind the microlens ML with respect to a path along which light travels, and may pass (e.g., selectively transmit) light having a designated reference color, for example, light having a designated wavelength range (e.g., a particular wavelength band of visible light) corresponding to a particular color of visible light. And where at least some of the color filters CF may be configured to selectively transmit light of at least two different wavelength bands from each other. In some example embodiments, a plurality of microlenses ML may be provided to correspond one-to-one with the pixels PX. Each microlens ML may at least partially overlap a separate corresponding color filter CF in a third direction D3. Accordingly, a corresponding color filter CF with regard to a microlens ML may refer to a color filter CF at least partially overlapping the microlens ML, where the microlens ML corresponding to a color filter CF of a given pixel is configured to condense light incident on the pixel and entering the photoelectric conversion element(s) PD of the given pixel through the corresponding color filter CF of the pixel PX.

In some example embodiments, the microlenses ML may have shapes varying depending on positions thereof. In the pixel array, the microlenses ML may be provided in different shapes to receive and condense light as much as possible depending on a direction in which the light enters, for example, an angle of incidence of the light. For example, when a central region of a pixel array is referred to as a first region R1 and an edge region of the pixel array is referred to as a second region R2, a shape of the microlenses ML in the first region R1 and a shape of the microlenses ML in the second region R2 may be different from each other. This will be described later.

The photoelectric conversion element PD may be disposed behind the microlens ML and the color filter CF and may correspond to, for example, a photodiode. When light reaches the photoelectric conversion element PD, an electrical signal corresponding to the incident light may be output by a photoelectric effect. The electric signal may generate charge (or current) based on the intensity of the received light.

In some example embodiments, a single pixel group PXG may include four pixels PX. According to some example embodiments, the plurality of pixel groups PXG may be arranged in a matrix to constitute an image sensor.

The single pixel group PXG may be arranged in a matrix in a first direction D1 and a second direction D2, intersecting each other. In the drawing, a direction perpendicular to the first and second directions D1 and D2 is a third direction D3.

The single pixel group PXG may include first to fourth pixels PX1, PX2, PX3, and PX4 arranged in a 2×2 matrix. A row direction may be the first direction D1, and a column direction may be the second direction D2. The first and second pixels PX1 and PX2 and the third and fourth pixels PX3 and PX4 may each be sequentially arranged in the first direction D1. In this case, the first and second pixels PX1 and PX2 may form a first row, and the third and fourth pixels PX3 and PX4 may form a second row.

Each of the first to fourth pixels PX1, PX2, PX3, and PX4 may include a first subpixel SPX1 and a second subpixel SPX2. The first and second subpixels SPX1 and SPX2 may be sequentially disposed in the first direction D1.

Among a plurality of reference colors, a single color may be assigned to the first to fourth pixels PX1, PX2, PX3, and PX4, such that the first to fourth pixels PX1, PX2, PX3, and PX4 may be configured to detect (e.g., photoelectrically convert) light of the particular single color assigned thereto. The plurality of reference colors may be, for example, RGB (red, green, blue), RGBW (red, green, blue, white), CMY (cyan, magenta, yellow), CMYK (cyan, magenta, yellow, black), RYB (red, yellow, blue), or RGBIR (RGB infrared ray). For example, a blue color (B), a green color (G), and a red color (R) will be described as being a first color, a second color, and a third color are described, but example embodiments are not limited thereto.

The color of the first to fourth pixels PX1, PX2, PX3, and PX4 may be implemented by color filters CF, respectively corresponding to pixels PX. When an array including color filters CF, respectively corresponding to pixels PX, is referred to as a color filter array, the color filter array may include first to third color filters CF1, CF2, and CF3, respectively corresponding to pixels PX. According to some example embodiments, the first to third color filters CF1, CF2, and CF3 may represent a blue color, a green color, and a red color, respectively. In addition, the first color filter CF1 may correspond to the first pixel, the second color filter CF1 may correspond to the second pixel PX2, the second color filter CF2 may correspond to the third pixel PX3, and the third color filter CF3 correspond to the fourth pixel PX4.

Hereinafter, a Bayer pattern, for example, an RGB pattern (or an RGGB pattern) will be mainly described for ease of description. However, it should be noted that the description does not intend to limit repeated arrangement structures and patterns of other color filters. For example, example embodiments are not limited thereto, and the color filter array may be formed in various patterns including RGB, CYYM, CYGM, RGBW, RYYB, or X-trans.

Referring to FIGS. 4A and 4B, in an image sensor according to some example embodiments, each pixel PX may include photoelectric conversion elements PD provided on a substrate 100.

The substrate 100 may have a first surface 100a, disposed in a direction in which light enters, and a second surface 100b opposing the first surface 100a.

The substrate 100 may be, for example, a semiconductor substrate including a semiconductor material such as a group IV semiconductor. For example, the group IV semiconductor may include silicon, germanium, or silicon-germanium. The substrate 100 may be provided as a bulk wafer, an epitaxial layer, a silicon on insulator (SOI) layer, a semiconductor on insulator (SeOI) layer, or the like. The substrate 100 may include impurity regions 105. For example, the substrate 100 may include a P-type silicon substrate. In some example embodiments, the substrate 100 may include a P-type bulk substrate and a P-type or N-type epitaxial layer grown thereon. In some example embodiments, the substrate 100 may include an N-type bulk substrate and a P-type or N-type epitaxial layer grown thereon. According to some example embodiments, the substrate 100 may include an organic plastic substrate. The image sensor may include, for example, a backside illumination type CMOS image sensor in which light enters the first surface 100a of the substrate 100.

A passivation layer PSV may include a plurality of layers, sequentially stacked on the first surface 100a of the substrate 100. For example, the passivation layer PSV may include at least two layers, among an aluminum oxide layer, a hafnium oxide layer, a tantalum oxide layer, a zirconium oxide layer, a silicon oxynitride layer, a silicon oxide layer, or a silicon nitride layer. In some example embodiments, the passivation layer PSV may include a fixed charge layer and/or an antireflection layer. The antireflection layer may be provided such that a reflective index is adjusted to allow incident light to travel the photoelectric conversion element at high transmittance.

The pixel PX may further include a photoelectric conversion element PD, a device isolation portion 107, and a pixel separation portion 110 disposed in the substrate 100, a pixel electrodes 120 disposed in a second insulating layer 140, and a grid layers 160, color filters (CF) CF1 and CF2, and microlenses ML disposed above the substrate 100.

The photoelectric conversion elements PD may be disposed in the substrate 100, and may absorb incident light to generate and accumulate a charge corresponding to the intensity of the light. The photoelectric conversion elements PD may include at least one of a photoelectric conversion element, a phototransistor, a photogate, a pinned photodiode (PPD), or combinations thereof. When the photoelectric conversion elements PD include a photoelectric conversion element, the photoelectric conversion elements PD may include an impurity region 105 having a conductivity type different from a conductivity type of the substrate 100 and may form a PN junction with a well region in the substrate 100.

The device isolation portions 107 may include an insulating material and may be disposed within the substrate 100 at a particular (or, in some example embodiments, predetermined) depth from the second surface 100b of the substrate 100.

The pixel separation portions 110 may be disposed in the substrate 100 below a boundary of each pixel PX. The pixel separation portions 110 may be connected to the device isolation portions 107 on the second surface 100b. However, an arrangement of the pixel separation portions 110 in the substrate 100 in the third direction D3 may vary according to some example embodiments. The pixel separation portions 110 may be disposed to surround the photoelectric conversion elements PD. However, a relative arrangement relationship between the pixel separation portions 110 and the photoelectric conversion elements PD is not limited to that illustrated in the drawing and may vary according to some example embodiments. The pixel separation portions 110 may include an insulating material or a conductive material. For example, when the pixel separation portions 110 include a conductive material, an insulating layer may be further provided between the pixel separation portions 110 and the substrate 100.

The pixel electrodes 120 may be disposed between the photoelectric conversion elements PD and the second wiring structure 130. The pixel electrodes 120 may constitute a pixel circuit of the pixel PX. For example, the pixel electrodes 120 may include a transfer gate constituting a transfer transistor. The transfer gate may be a vertical transistor gate including a portion extending inwardly of the substrate 100 from the second surface 100b of the substrate 100. The pixel electrodes 120 may further include a floating diffusion region FD in the substrate 100 and gates on the second surface 100b of the substrate 100, other than the transfer gate. The gates may constitute a source-follower transistor, a reset transistor, and a select transistor.

The grid layers 160 may be disposed between the color filters CF on the passivation layer PSV to separate the color filters CF from each other. The grid layers 160 may be disposed on the passivation layer PSV, and may be disposed below the boundary of each pixel PX. The grid layers 160 may be disposed above the pixel separation portions 110 in the third direction D3, perpendicular to one surface of the substrate 100. The grid layer 160 may be provided as a multilayer structure and may include at least one of metal materials such as titanium (Ti), titanium oxide, tantalum (Ta), or tantalum oxide. Also, the grid layer may be an insulating layer, a low refractive index (LRI) layer, and may have a refractive index within a range of, for example, about 1.1 to about 1.8. The grid layer may include an insulating material such as silicon (Si), aluminum (Al), or an oxide or nitride including a combination thereof, and may include a silicon oxide having a porous structure or silica nanoparticles having a network structure. In some example embodiments, a protective layer may be further provided to cover a first surface and side surface of the grid layers 160 and to extend upwardly of the passivation layer PSV.

The color filters (CF) CF1 and CF2 may be disposed on the passivation layer PSV and the grid layers 160 above the photoelectric conversion elements PD. For example, the color filters CF may include a first color filter CF1, provided in the first pixel PX1, and a second color filter CF2 provided in the second pixel PX2. The color filters CF may allow (e.g., selectively transmit) light of a specific wavelength (e.g., a particular wavelength band) to pass therethrough and then to reach the lower photoelectric conversion elements (PD) PD1 and PD2. The color filters CF may be implemented as a color filter array including a red filter, a green filter, and a blue filter configured to selectively transmit light of the red wavelength band, the green wavelength band, and the blue wavelength band, respectively. The color filter CF may be formed of, for example, a material obtained by mixing a resin with a pigment containing a metal or a metal oxide.

The microlenses (ML) ML1 and ML2 may be disposed on the color filters CF to change a path of light entering a region other than the photoelectric conversion elements PD and to condense the light into the photoelectric conversion elements PD. The microlenses ML may be formed of a transparent polymer material. The microlenses ML may be formed of, for example, a transparent photosensitive material or a transparent thermosetting resin. The microlenses ML may include, for example, a TMR-based resin (Tokyo Ohka Kogyo, Co., Ltd.) or an MFR-based resin (Japan Synthetic Rubber (JSR) Corporation). However, the material of the microlenses ML is not limited thereto, and various materials may be used as the material of the microlenses ML.

In some example embodiments, each microlens ML may be formed to have a shape varying for each region to improve an autofocusing function using a phase difference. In some example embodiments, a symmetrical lens ML and an asymmetrical lens ML may be used for a central region (for example, the first region R1) of the pixel array and an edge region (for example, the second region R2) of the pixel array (see FIG. 3A), respectively. According to an angle of light entering the image sensor, the intensity of light incident in a relatively vertical direction is high in the central region and the intensity of light incident in a relatively inclined direction is high in the edge region.

In some example embodiments, each pixel PX may include a first subpixel SPX1 and a second subpixel SPX2. Therefore, the first and second subpixels SPX1 and SPX2 in a single pixel PX may share a single microlens ML. For example, the first and second subpixels SPX1 and SPX2 within the first pixel PX1 may share a single first microlens ML1, and the first and second subpixels SPX1 and SPX2 within the second pixel PX2 may share a single second microlens ML2.

The first and second sub-pixels SPX1 and SPX2 of each pixel PX may share a single microlens ML, and may each include an additional photoelectric conversion element PD. For example, the first and second subpixels SPX1 and SPX2 in the first pixel PX1 may include first and second photoelectric conversion elements PD1 and PD2, respectively. In addition, the first and second subpixels SPX1 and SPX2 in the second pixel PX2 may include first and second photoelectric conversion elements PD1 and PD2, respectively.

Accordingly, additional incident light may enter each of the first and second subpixels SPX1 and SPX2, and a phase difference of light provided to the first and second subpixels SPX1 and SPX2 may be obtained. Autofocusing of the image sensor may be performed by measuring a phase difference of light entering a single pixel PX. When each pixel PX is not used for autofocusing, an image signal may be obtained. In this case, a method of collecting information of the first and second subpixels SPX1 and SPX2 may be used. As described above, the image sensor according to some example embodiments may use all pixels PX to perform autofocusing and to obtain image signals. As necessary, only some pixels are used to perform autofocusing and the remaining pixels may be used to obtain image signals.

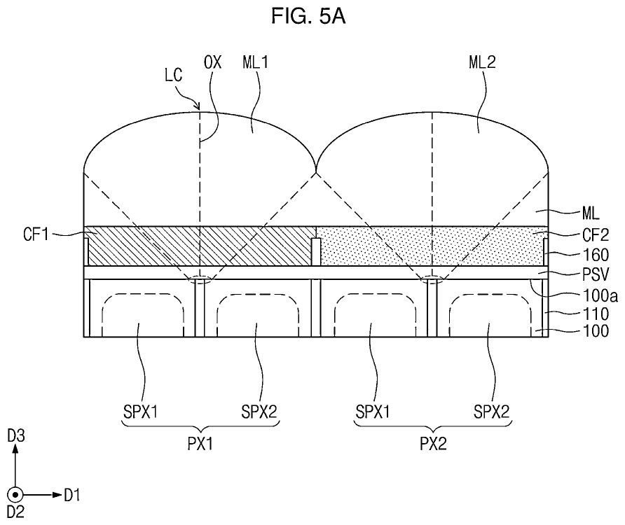

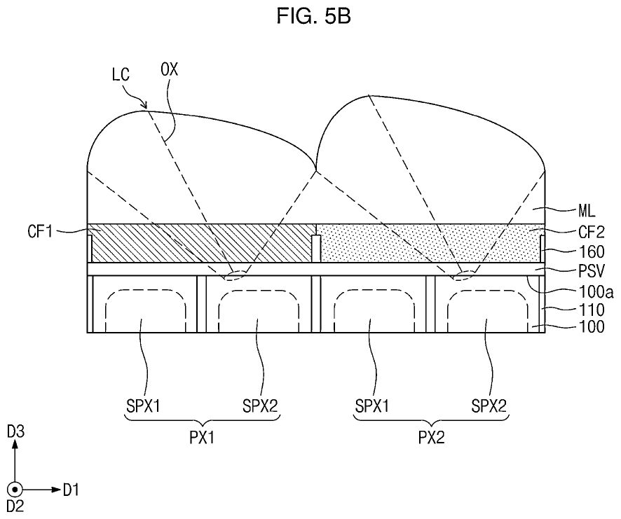

FIGS. 5A and 5B are cross-sectional views illustrating portions of two adjacent pixels together with an optical path according to some example embodiments. FIG. 5A illustrates a portion of another pixel disposed in the first region, and FIG. 5B illustrates a portion of a pixel disposed in the second region.

Referring to FIG. 5A, a microlens ML disposed in the first region R1 (see FIG. 3A) may have a symmetrical shape on a single pixel PX with respect to a center of the pixel PX. For example, the microlens ML disposed in the first region R1 may be horizontally symmetric with respect to a line passing through the center of the pixel PX when the microlens ML is cut along a plane, perpendicular to a surface of the substrate 100, in a direction parallel to the first direction D1 while passing through the center of the pixel PX. Accordingly, in a single microlens ML, a portion of the single microlens ML that is uppermost in an upward direction, for example, a third direction D3 (hereinafter referred to as an uppermost point LC, a point of the microlens ML protruding furthest in the third direction D3, etc.) may overlap or substantially overlap the center of the pixel PX.

Since the microlens ML of the first region R1 has a symmetrical shape, the uppermost point of the microlens ML may be a center of the lens and a focal position may overlap or substantially overlap the center of the pixel PX in the third direction D3. Accordingly, a line OX connecting the uppermost point LC and the focal position may be perpendicular or substantially perpendicular to an upper surface of the substrate 100.

Referring to FIG. 5B, a microlenses ML disposed in the second region R2 (see FIG. 3A) may be provided on a single pixel PX to be symmetrical in a specific direction. For example, when viewed on a cross-section taken in a direction, parallel to a first direction D1, while passing through a center of the pixel PX, the microlens ML disposed in the second region R2 may be asymmetrical with respect to a line passing though the center of the pixel PX. Since the microlens ML according to some example embodiments has an asymmetrical shape, an uppermost point LC of the microlens does not match the center of the pixel PX (e.g., is spaced apart from the center of the corresponding pixel PX on a plane, such as a plane extending in the first and second directions D1 and D2). The uppermost point LC of the microlens ML may refer to a distance protruding furthest from one of an upper surface of the substrate 100 or a lower surface of the microlens ML in a third direction D3.

In the asymmetrical shape, the uppermost point LC may be disposed on one side from the center of the pixel PX and may be disposed on the side of a direction, in which light is incident, such that light inclined from a side is incident. For example, when light is obliquely incident from left to right with respect to the center of the pixel PX, the uppermost point LC may be disposed on a left side with respect to the center of the pixel PX. In contrast, when light is obliquely incident from right to left with respect to the center of the pixel PX, the uppermost point LC may be disposed on a right side with respect to the center of the pixel PX. Accordingly, in the image sensor, the microlenses ML of each pixel PX disposed in the second region R2 have an uppermost point in a direction of the first region R1, for example, on a side viewed from a center of a pixel region. For example, in the pixel array PA of FIG. 2A, a distance between an uppermost point LC of each respective microlens ML of the microlenses and a center of a corresponding pixel PX of the plurality of pixels at least partially overlapping the respective microlens ML in the third direction D3 may increase in a direction toward an edge portion of the pixel region PA (e.g., the second region R2) from a central portion of the pixel region PA (e.g., first region R1).

As a result, in the single microlens ML, the uppermost point LC from the lower surface does not overlap the center of the pixel PX in the third direction D3. For example, in two adjacent cells, a point corresponding to the uppermost point of each of the first and second microlenses ML1 and ML2 is disposed in a position, different from the centers of the first and second pixels PX1 and PX2.

The focal position of the microlenses ML, disposed in the second region R2, also does not match the center of the pixel PX. Accordingly, a line connecting the uppermost point LC and the focus may be inclined on an upper surface of the substrate 100 at a particular (or, in some example embodiments, predetermined) angle.

A point, at which the focus is formed, may be a position in which photoelectric conversion efficiency is significantly increased because incident light is condensed to result in high intensity thereof. The point, at which the focus is formed, may be the inside of the substrate 100, for example, the inside of a photoelectric conversion element. In some example embodiments, the point at which focus is formed may be indicated as the upper surface of the substrate 100. However, this is only an example for ease of description, and example embodiments are not limited thereto.

According to some example embodiments, the microlenses ML has an asymmetrical shape, so that an angle of incidence of light incident from a side may be secured to be significantly large. This will be described as follows.

As illustrated in FIG. 5A, when the microlens ML has a symmetrical shape, light having a small incident angle may be sufficiently detected. However, when an incident angle is large, for example, when light entering the microlens ML is incident from a side, a detectable angular width is inevitably reduced. In this case, the chief ray angle (CRA) may be reduced. On the other hand, as illustrated in FIG. 5B, when the microlens ML has an asymmetrical shape, an angle of light incident from a side may be offset by the asymmetrical shape. Thus, sensitivity may be improved to increase an angular width. In this case, excellent performance may be exhibited at a relatively large CRA.

As a result, when the microlens ML of the second region R2 is formed to be asymmetrical according to some example embodiments, the sensitivity of the image sensor to light incident from a side may be improved, and thus the functionality (e.g., photoelectric conversion performance, photoelectric conversion efficiency, etc.) of the image sensor may be improved.

The microlens ML according to some example embodiments may have a shape to perform correction of chromatic aberration based on each color, other than a change in path of light from a side portion through a change in shape.

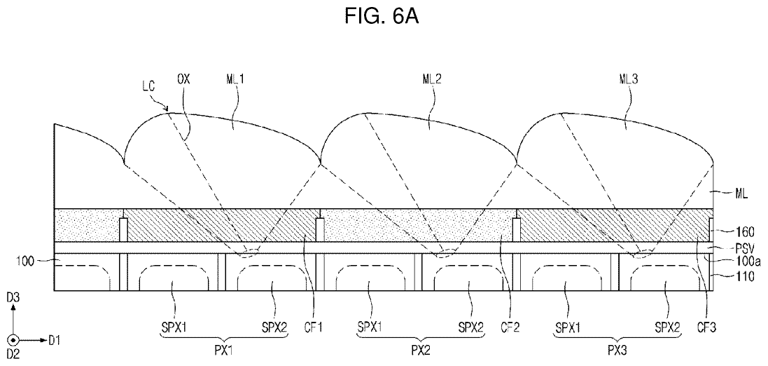

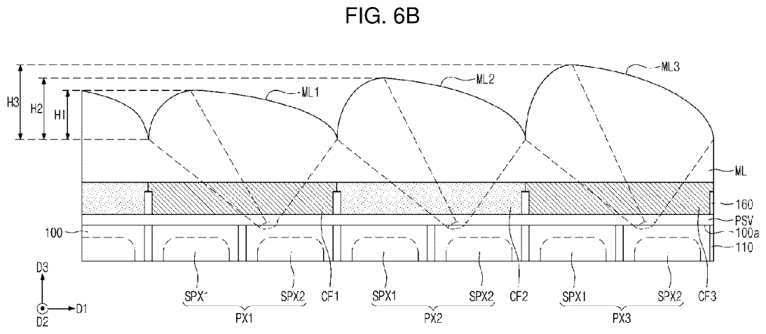

FIGS. 6A and 6B are cross-sectional views illustrating only microlens portions and an optical path when a shape of a microlens in the second region is changed according to some example embodiments. FIG. 6A is diagram illustrating an optical path when microlenses are manufactured in the same size and shape regardless of colors, and FIG. 6B is a diagram illustrating an optical path when microlenses are manufactured in different sizes and shapes corresponding to colors.

In the drawings, first to third pixels PX1, PX2, and PX3 having first to third color filters CF1, CF2, and CF3 are illustrated as being arranged in a row for ease of description of comparison between pixels PX. An example is provided in which the first to third color filters CF1, CF2, and CF3 are illustrated in the case in which wavelengths selectively transmitted by the first to third color filters CF1, CF2, and CF3 are sequentially increased. For example, the first to third color filters CF1, CF2, and CF3 may be configured to selectively transmit different wavelength bands of light from each other. The first to third color filters CF1, CF2, and CF3 may be configured to selectively transmit sequentially longer wavelengths, such that the second color filter CF2 is configured to selectively transmit a longer wavelength than the first color filter CF1, and the third color filter CF3 is configured to selectively transmit a longer wavelength than the second color filter CF2. In detail, a case in which the first to third color filters CF1, CF2, and CF3 respectively correspond blue, green, and red colors (e.g., are respectively blue, green, and red color filters) is illustrated as an example.

Referring to FIGS. 6A and 6B, light passing through first to third microlenses ML1, ML2, and ML3 may have different refractive indices depending on a color thereof. Accordingly, there may be a difference in optical paths. A refractive index may vary depending on a material constituting the microlenses ML, but the microlenses ML may have chromatic aberration in which a refractive index is decreased as a wavelength of light passing through the microlenses ML is increased. For example, a wavelength of blue light passing through the first color filter CF1 is the shortest, and thus a refractive index is the highest. On the other hand, a wavelength of red light passing through the third color filter CF3 is the longest, and thus a refractive index is the lowest. As a result, a focal length may be different for each pixel PX due to a difference in refractive indices depending on a wavelength of light passing through the first to third color filters CF1, CF2, and CF3. The light passing through the first to third color filters CF1, CF2, and CF3 may sequentially have a longer focal length, and thus a focus may be formed not only in a deeper place but also in different positions even when viewed in plan view. Such a difference in optical paths for each color may cause defocusing of the focus and may have an adverse effect on autofocusing.

In some example embodiments, the microlens ML may be formed to have a shape to compensate for chromatic aberration for each pixel PX corresponding to each color. To this end, the first to third microlenses ML1, ML2, and ML3 may be changed in shape, for example, height, radius of curvature, or the like, to correspond to a color such that a focal length is changed for each color. Accordingly, an optical path caused by chromatic aberration may be corrected. As a result, a focus may be formed at a desired point regardless of color. For example, at least some microlenses ML may have different shapes depending on respective wavelength bands that respective corresponding color filters CF at least partially overlapping in the third direction D3 with (e.g., corresponding to) the at least some microlenses ML are configured to selectively transmit, such that the at least some microlenses ML are configured to compensate for chromatic aberration between the lights passing through the respective corresponding color filters CF. For example, referring to FIGS. 6A-6B, the first to third microlenses ML1 to ML2, respectively on (e.g., corresponding to) the first to third color filters CF1, CF2, and CF3, may have different shapes from each other based on the different, respective wavelength bands of light that the first to third color filters CF1, CF2, and CF3 are respectively configured to selectively transmit.

In some example embodiments, the microlens ML of the second region R2 has been described as an example, but a change in the shape thereof for correcting chromatic aberration may be equally applied to the microlens ML of the first region R1.

According to some example embodiments, the first to third microlenses ML1, ML2, and ML3 may have different heights to correct an optical path caused by chromatic aberration. The height of the microlens ML may refer to a distance between uppermost points LC of the microlenses ML each protruding from one of an upper surface or a lower surface of the substrate 100 in a third direction D3. A relative height between the microlenses ML may refer to a distance between uppermost points LC of the microlenses ML with respect to a plane, parallel to the upper surface of the substrate 100, as well as the upper surface of the substrate 100 or a lower surface of the microlens ML.

For example, the first microlens ML1 corresponding to light having a shortest wavelength may be provided at a smallest height, and the second microlens ML2 corresponding to light having a longest wavelength may be provided at a largest height. When heights from lower surfaces of the first to third microlenses ML1, ML2, and ML3 to the respective uppermost points LC of the first to third microlenses ML1, ML2, and ML3 are respectively referred to as first to third heights H1, H2, and H3, the first to third heights H1, H2, and H3 may be sequentially increased, for example such that a second height H2 of an uppermost point of the second microlens ML2 is greater than a first height H1 of an uppermost point of the first microlens ML1, and a third height H3 of an uppermost point of the third microlens ML3 is greater than the second height H2 of the uppermost point of the second microlens ML2.

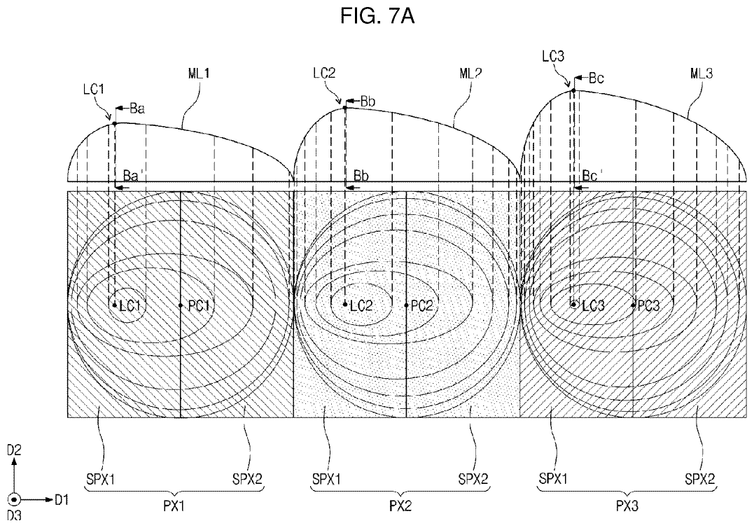

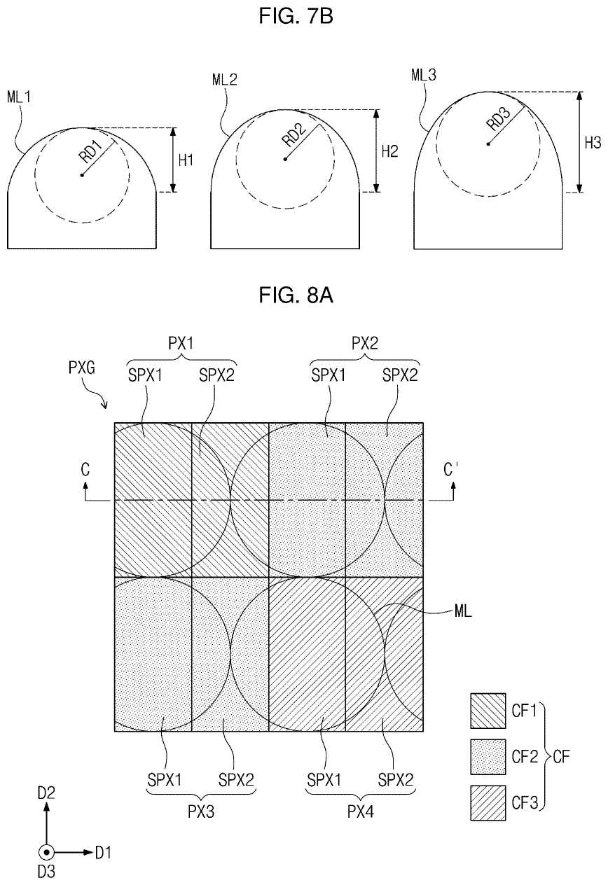

FIG. 7A is a diagram illustrating a portion of microlenses according to some example embodiments and the diagram of FIG. 7A includes a cross-sectional view and a corresponding contour diagram illustrating first to third microlenses among the microlenses of FIG. 6B according to some example embodiments, and FIG. 7B includes drawings illustrating cross-sections when the first to third microlenses are taken along lines BaBa′, BbBb′, and BcBc′ according to some example embodiments.

Referring to FIGS. 7A and 7B, the first to third microlenses ML1, ML2, and ML3 may have different heights and different radii of curvature depending on colors (e.g., respective colors that the first to third color filters CF1, CF2, and CF3 respectively corresponding to the first to third microlenses ML1, ML2, and ML3 are configured to selectively transmit). For example, the first to third microlenses ML1, ML2, and ML3 may have different radii of curvature at uppermost points LC1, LC2, and LC3. In the first to third microlenses ML1, ML2, and ML3, the radii of curvature may be selected in consideration of a focal position or an angle of incidence from a side portion and may be increased in a direction from the first microlens ML1 toward the third microlens ML3. For example, when radii of curvature at the uppermost points of the first to third microlenses ML1, ML2, and ML3 are respectively referred to as first to third radii of curvature RD1, RD2, and RD3, the second radius of curvature RD2 may be greater than the first radius of curvature RD1 and the third radius of curvature RD3 may be greater than the second radius of curvature RD2. Accordingly, the second microlens ML2 may have a greater radius of curvature than the first microlens ML1, and the third microlens ML3 may have a greater radius of curvature than the second microlens ML2.

Areas of the first to third microlenses ML1, ML2, and ML3 may be the same when viewed in plan view, but areas of the first to third microlenses ML1, ML2, and ML3 at a specific height may be different from each other. For example, when the first to third microlenses ML1, ML2, and ML3 are cut along contour lines, shapes thereof may also be different from each other. Lowermost surfaces of the first to third microlenses ML1, ML2, and ML3 may have the same circular shape, but may have different shapes depending on a position of a contour line, for example, elliptical shapes with major axes and minor axes having different sizes.

In some example embodiments, the first to third microlenses ML1, ML2, and ML3 may have circular or elliptical shapes as described above, but example embodiments are not limited thereto. The shapes of the first to third microlenses ML1, ML2, and ML3 may be modified into various shapes as long as they are provided on each pixel to condense as much light as possible and to provide the condensed light to a photoelectric conversion element PD. For example, the first to third microlenses ML1, ML2, and ML3 may be provided in different shapes depending on a shape of each pixel. When pixels are provided in a rectangular shape, the first to third microlenses ML1, ML2, and ML3 may also be provided in a rectangular shape. In this case, the first to third microlenses ML1, ML2, and ML3 may cover each pixel as much as possible. Also, when the pixels are provided in a shape other than the rectangular shape, such as a hexagonal shape or an octagonal shape, the shapes of the first to third microlenses ML1, ML2, and ML3 may also be modified to correspond thereto. In some example embodiments, the shapes of the first to third microlenses ML1, ML2, and ML3 may be provided separately from the shapes of the pixels.

In some example embodiments, in some example embodiments, including the example embodiments shown in FIGS. 7A-7B, the first to third microlenses ML1, ML2, and ML3 may formed to cover as many of the first to third pixels PX1, PX2, and PX3, corresponding thereto with the same areas, as much as possible. However, example embodiments are not limited thereto, and areas of the first to third microlenses ML1, ML2, and ML3 on a lowermost surface may also be set to be different.

Further, in each of the microlenses ML, curvatures at points forming a curved surface may be different from each other. For example, a radius of curvature at a point close to each of the uppermost points LC1, LC2, and LC3 of the microlenses ML may be relatively small, and a radius of curvature at each of the uppermost points LC1, LC2, and LC3 of the microlenses ML may be relatively large. In some example embodiments, a radius of curvature between each of the uppermost points LC1, LC2, and LC3 and each lowermost point of the microlenses ML may be relatively small, then increase, and then decrease again.

In some example embodiments, including the example embodiments illustrated in FIGS. 7A and 7B, the uppermost points LC1, LC2, and LC3 of the first to third microlenses ML1, ML2, and ML3 are illustrated as being spaced apart from centers of the first to third pixels PX1, PX2, and PX3 at regular intervals in the first direction D1. However, example embodiments are not limited thereto, and a distance therebetween may vary depending on the degree of compensation for chromatic aberration.

In some example embodiments, the microlenses have an asymmetrical shape, so that light efficiency of lights incident from a side may be improved, but a focal position may be spaced apart from a center of a pixel. In some example embodiments, an offset structure may be formed by shifting the microlenses by a particular (or, in some example embodiments, predetermined) distance in a particular (or, in some example embodiments, predetermined) direction such that a focal position is disposed in the center of the pixel or disposed as close to the center of the pixel as possible rather than even the center of the pixel. The offset structure refers to a configuration in which overlapping areas (e.g., regions) of a pixel and a corresponding microlens mismatch (e.g., are offset by at least a first distance). and offset distance (e.g., the first distance at which the region of a microlens and the region of a corresponding pixel are offset in the first direction D1) may increase in the direction toward the edge portion (e.g., second region R2) of the pixel region PA from the central portion (e.g., first region R1) of the pixel region PA. For example, in the above-described example embodiments, each microlens has a structure completely overlapping a corresponding pixel, so that such a structure is not an offset structure. However, in some example embodiments, at least a portion of the microlenses may move a particular (or, in some example embodiments, predetermined) distance from a center of the corresponding pixel in a particular (or, in some example embodiments, predetermined) direction, for example, in a direction of light incident from a side, so that a corresponding microlens and a pixel may partially overlap each other. Therefore, such a structure may be referred to as an offset structure.

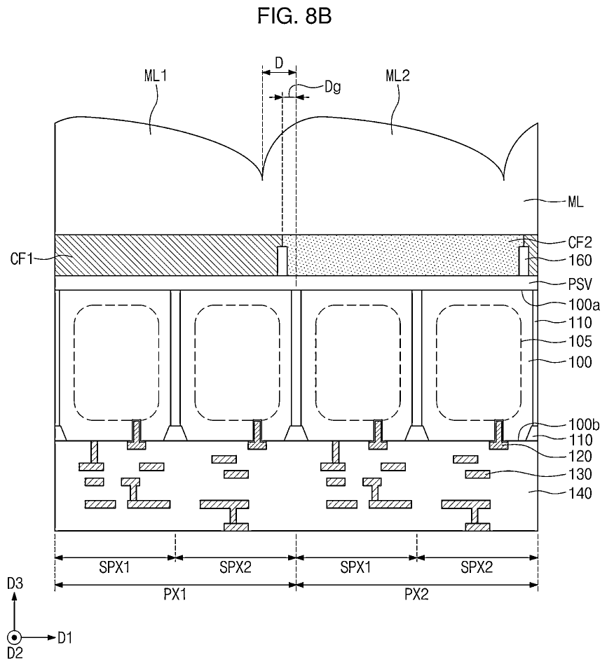

FIG. 8A is a diagram illustrating an example of a pixel group having an offset structure according to some example embodiments, and FIG. 8B is a cross-sectional view taken along line C-C′ of FIG. 8A according to some example embodiments.

Referring to FIGS. 8A and 8B, a microlens ML corresponding to each pixel PX may be moved by a particular (or, in some example embodiments, predetermined) distance D in a particular (or, in some example embodiments, predetermined) direction (a direction opposite to the first direction D1 in the drawings) to partially overlap the corresponding pixel PX. For example, a first microlens ML1 may correspond to a first pixel PX1 and the second microlens ML2 may correspond to a second pixel PX2. A portion of the first microlens ML1 may overlap the first microlens ML1, and remaining portions of the first microlens ML1 may overlap another pixel PX adjacent to the first pixel PX1. Similarly, a portion of the second microlens ML2 may overlap the second pixel PX2, and remaining portions of the second microlens ML2 may overlap the adjacent first pixel PX1.

A direction, in which the microlens ML moves, may be a direction in which an uppermost point of the microlens ML is present, and the microlens ML may be shifted by a particular (or, in some example embodiments, predetermined) distance in the direction. As the microlens ML is shifted in a particular (or, in some example embodiments, predetermined) direction, an asymmetrical shape may prevent a focus of incident light from deviating from a pixel PX. For example, the asymmetrical microlens ML may move to the extent that a focus of the microlens ML deviates from s center of the pixel PX, allowing the focus to correspond to the center of the pixel PX.

In some example embodiments, color filters CF1 and CF2 and a grid layer 160, disposed below the microlens ML on an optical path, may be shifted to that extent. Accordingly, the color filters CF1 and CF2 and the grid layer 160 may also have offset structures. However, the shift amount of the offset structures of the color filters CF1 and CF2 and the grid layer 160 may be equal to or less than the shift amount of the microlenses. For example, as described above, when a moving distance of a microlens is referred to as D and a moving distance of color filters and/or a grid layer is referred to as Dg, Dg may have a value equal to or less than D. The offset structures of the color filters CF1 and CF2 and the grid layer 160 may be implemented to a different extent depending on a position of a pixel region, an optical path, a color filter, or the like.

By simultaneously or independently controlling an asymmetrical shape itself, for example, heights or radii of curvature of the microlens ML other than shifting the microlens ML, the shape of the microlens ML may be modified such that a focus of the microlens ML is disposed in the center of the pixel PX.

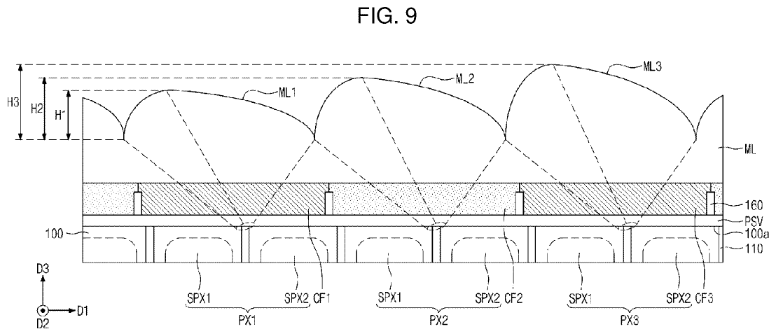

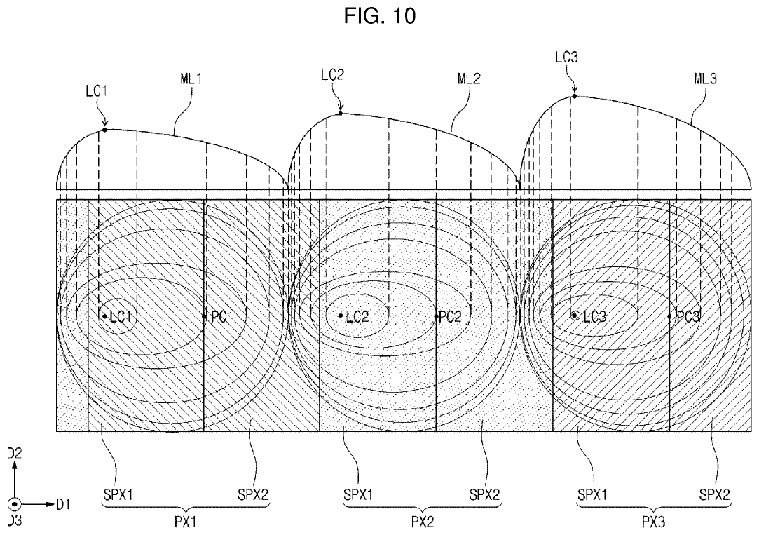

FIG. 9 is a diagram illustrating an optical path when microlenses are manufactured in different sizes and shapes corresponding to colors and are formed in an offset structure according to some example embodiments. FIG. 10 is a diagram illustrating a portion of microlenses according to some example embodiments, and the diagram of FIG. 10 includes a cross-sectional view and a corresponding contour diagram illustrating first to third microlenses according to some example embodiments.

Referring to FIGS. 9 and 10, first to third microlenses ML1, ML2, and ML3 may be partially shifted in a direction opposite to a first direction D1. Accordingly, the first microlens ML1 may mostly overlaps a first pixel PX1 but a portion thereof may overlap other pixels adjacent to the first pixel PX1, the second microlens ML2 may mostly overlap a second pixel PX2 but a portion thereof may overlap the first pixel PX1, and the third microlens ML3 may mostly overlap a third pixel PX3 but a remaining portion thereof may overlap the second pixel PX2. A portion of the third pixel PX3 may overlap a microlens ML of another pixel PX adjacent to the third pixel PX3. As described above, the microlenses ML may be moved to form a focus in a center of each pixel PX in the case of incident lights passing through the asymmetrical microlenses ML. Thus, light may be incident into each pixel PX with maximum light efficiency.

In some example embodiments, the shift amount of the microlenses ML may be equally set for each pixel PX, but example embodiments are not limited thereto. For example, the shift amount of the microlenses ML, for example, a moving distance of the microlenses ML may vary depending on a shape of the microlens ML, a thickness of a lower portion of the microlens ML, the type of color, or the like. In addition, the microlenses may be shifted by a particular (or, in some example embodiments, predetermined) distance to a different extent according to a distance from a central portion of the pixel region PA and according to an amount of asymmetry of the microlenses ML. For example, a shifted distance may be increased in a direction away from the central portion of the pixel region PA. However, example embodiments are not limited thereto, and an offset structure may be formed by shifting the microlenses ML in a specific direction in an active region of the entire image sensor.

As described in some example embodiments, when the microlens is asymmetrically formed and shifted in a particular (or, in some example embodiments, predetermined) direction by a particular (or, in some example embodiments, predetermined) distance, focus broadening may be prevented separately from placing the focus of the microlens within a pixel.

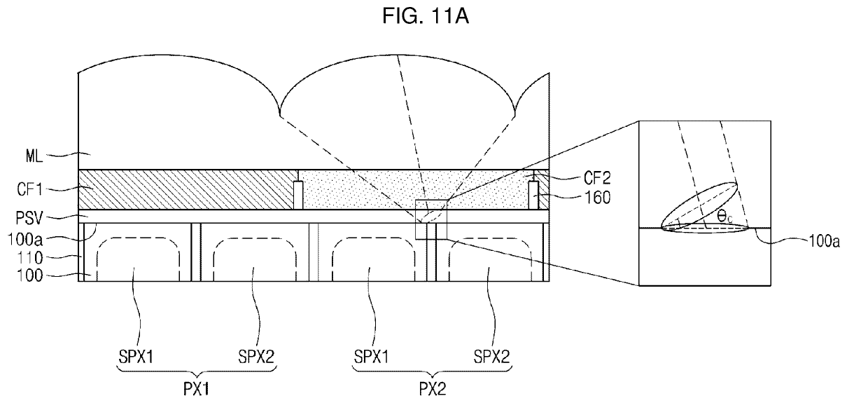

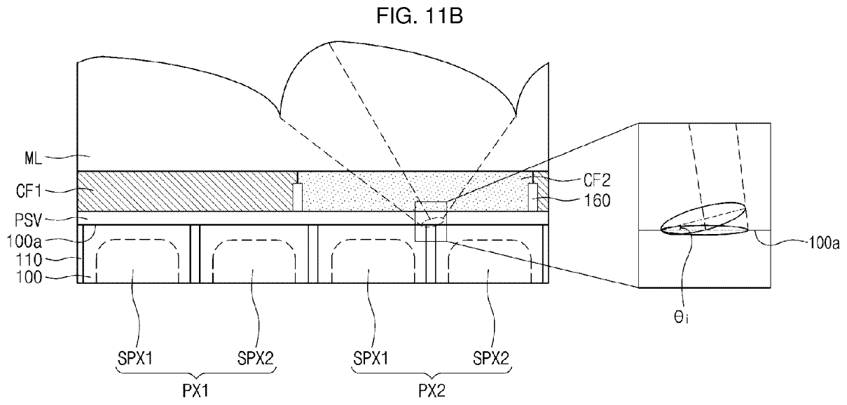

FIGS. 11A and 11B are diagrams illustrating the degree of broadening for different microlens formations according to some example embodiments. FIG. 11A is a cross-sectional view illustrating a case in which a symmetrical microlens is used, and FIG. 11B is a cross-sectional view illustrating a case in which an asymmetrical microlens is used.

Referring to FIGS. 11A and 11B, when a structure of using a symmetrical microlens ML and shifting the microlens ML is applied even to a pixel PX in a second region R2 with a large angle of incidence of incident light, a CRA may be small and a plane, on which a focus of light is formed, may be inclined at a particular (or, in some example embodiments, predetermined) angle θ_{c} with respect to a plane parallel to an upper surface of a substrate 100. As a result, such an inclined focal plane may cause focus broadening in which a focal plane is broadened when light is projected onto the upper surface of the substrate 100. For example, angles of incidence of lights incident on a central portion of a pixel array and an edge of the pixel PX may be different from each other. For example, the angle of incidence of the light incident on the edge of the pixel PX may be greater than the angle of incidence of the light incident on the center of the pixel PX. Accordingly, light detection performance of a pixel PX disposed at an edge of the pixel PX may inevitably deteriorate due to a chief-ray angle (CRA) of light incident to the microlenses, for example, as CRA is increased. As a result, autofocusing performance may rapidly deteriorate. Such deterioration of autofocusing performance may be affected by a difference in broadening of a focal plane during focusing based on an angle of incidence of incident light.

In some example embodiments, a structure using an asymmetrical microlens may be employed in a pixel to control a refraction degree in a way that broadening of a focal plane is significantly reduced according to an angle of incidence of light incident to the microlenses ML. A plane, using such an asymmetrical microlens in a pixel and on which a focus of incident light is formed, has a smaller angle to the first surface 100a of the substrate 100 than the particular (or, in some example embodiments, predetermined) angle θ_{c}. Accordingly, even in the structure according to some example embodiments, the inclined focal plane is broadened when light is projected onto the upper surface of the substrate 100 but the angle is smaller than an angle of a microlens ML according to the related art. Therefore, the degree of broadening may be significantly reduced. As a result, deterioration of autofocusing performance of the pixel PX in an edge region may be suppressed.

As described above, in some example embodiments, a structure using an asymmetrical microlens may be employed in a pixel to control a refraction degree in a way that broadening of a focal plane is significantly reduced according to an angle of incidence of light incident to microlenses. In this regard, an optical path of the incident light in the symmetrical microlens and the asymmetrical microlens will be described as follows.

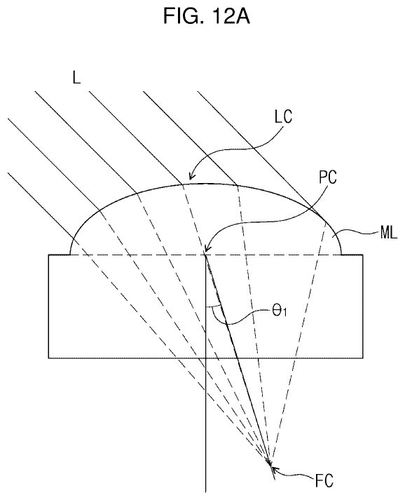

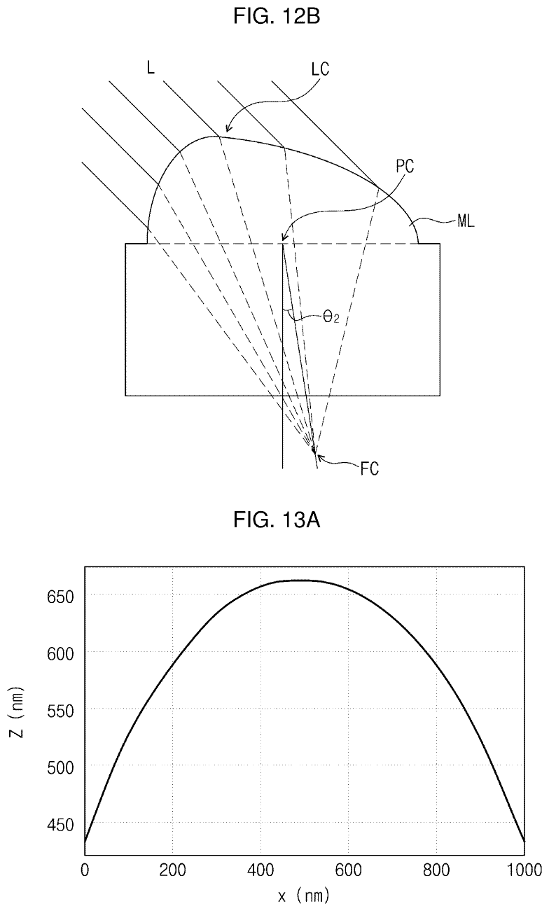

FIGS. 12A and 12B are cross-sectional views illustrating only optical paths of a symmetrical microlens and an asymmetrical microlens according to some example embodiments.

Referring to FIGS. 12A and 12B, when light L is incident at the same angle to a symmetrical microlens ML and an asymmetrical microlens ML, a focus may be formed at a point having a specific angle to a line, passing through a center of a substrate 100, in both the symmetrical microlens ML and the asymmetrical microlens ML when viewed in plan view.

Since the symmetrical microlens ML is formed to be symmetrical with respect to a center PC of a pixel PX, for light L incident in a lateral direction, a focus may be formed at a point significantly spaced apart from a center of a pixel PX by a first angle θ₁. In contrast, the asymmetrical microlens ML may include a lens formed to be asymmetrical in a direction of light incident from a side, so that a focus FC may be formed at a point spaced at a second angle θ₂, significantly smaller than an angle formed with respect to the light L incident in a lateral direction by a microlens according to the related art. As a result, an angle of light passing through the asymmetrical microlens ML may be corrected by a difference between the first angle θ₁ and the second angle θ₂ (θ₁-θ₂, hereinafter referred to as a “correction angle”) to form a focus FC at a point near a center of a pixel PX.

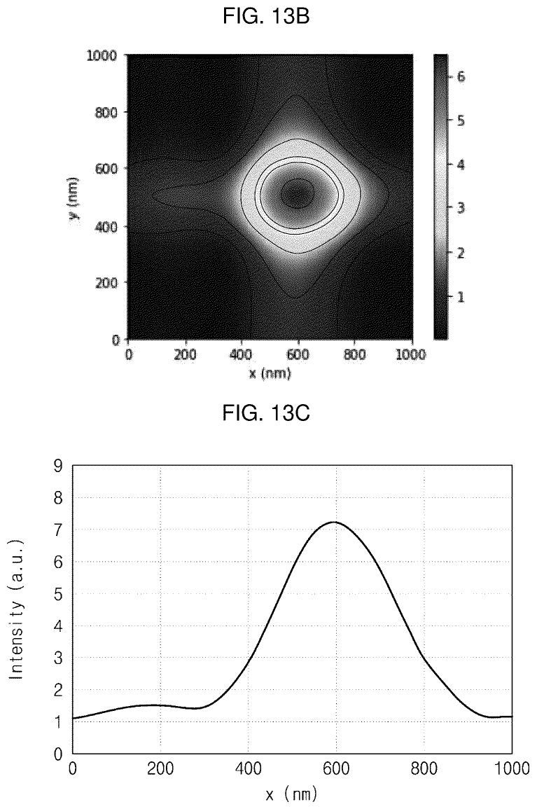

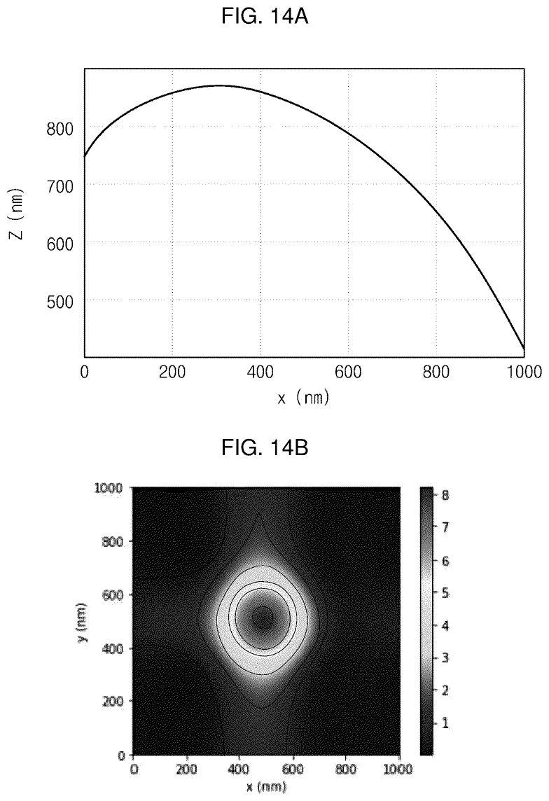

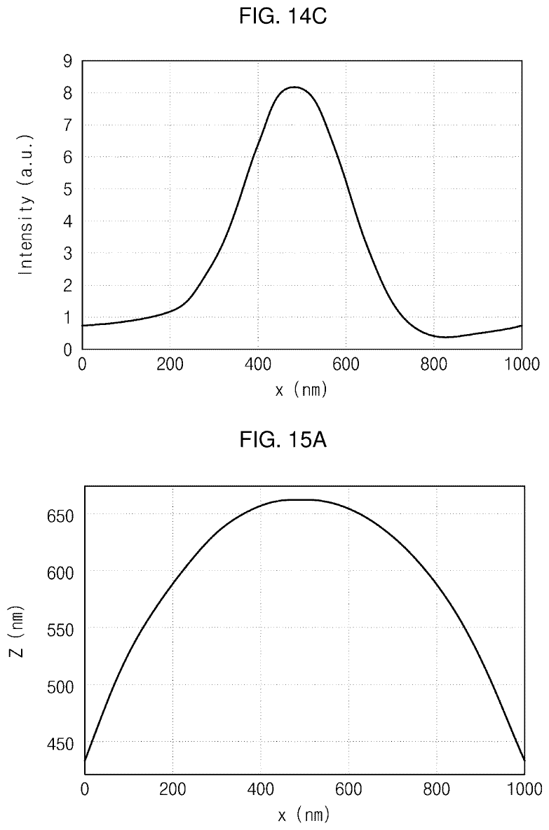

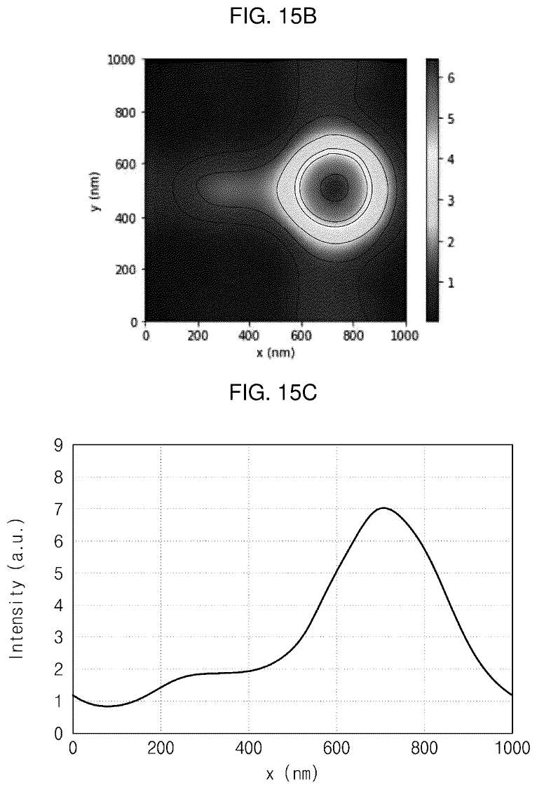

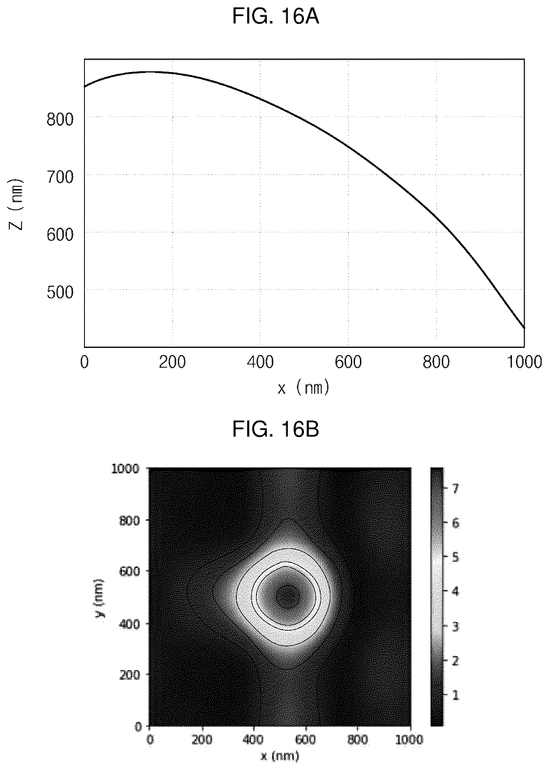

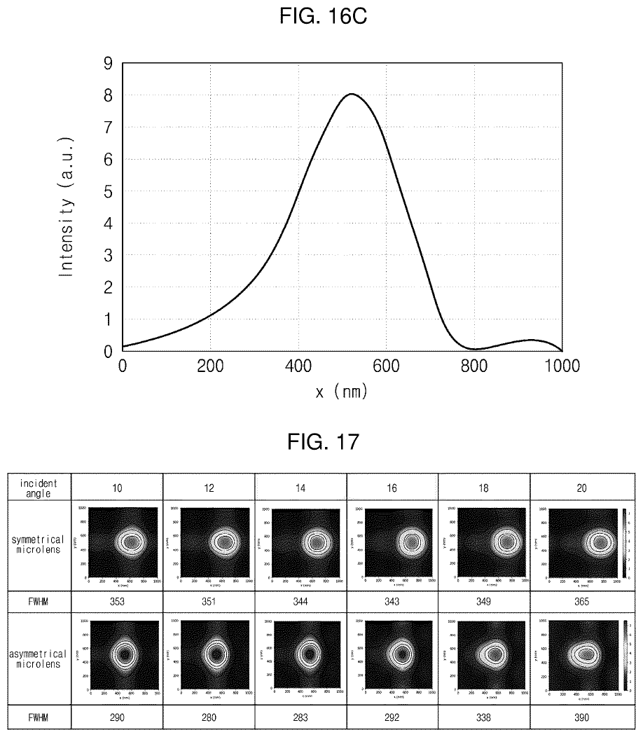

FIGS. 13A, 13B, and 13C and FIGS. 14A, 14B, and 14C are diagrams illustrating an optical path correction effect using a symmetrical microlens and an asymmetrical microlens when an angle of incidence of light entering a microlens having a thickness of 500 nm is 10 degrees according to some example embodiments. FIGS. 15A, 15B, and 15C and FIGS. 16A, 16B, and 16C are diagrams illustrating an optical path correction effect using a symmetrical microlens and an asymmetrical microlens when an angle of incidence of light entering a microlens having a thickness of 500 nm is 20 degrees according to some example embodiments.

FIGS. 13A, 14A, 15A, and 16A are graphs each illustrating a shape of a lens, FIGS. 13B, 14B, 15B, and 16B are rigorous coupled-wave analysis (RCWA) images. FIGS. 13C, 14C, 15C, and 16C are graphs each illustrating the intensity of light depending on a position on a pixel, and a position on an X-axis, a center of the pixel, corresponds to a point of 500 nm.

Referring to FIGS. 13A to 13C, 14A to 14C, 15A to 15C, and 16A to 16C, it can be seen that the intensity of light is higher in a center of an asymmetrical microlens than in a center of a symmetrical microlens. This means that a focus of the asymmetrical microlens is formed closer to the center of a pixel than a focus of the symmetrical microlens.

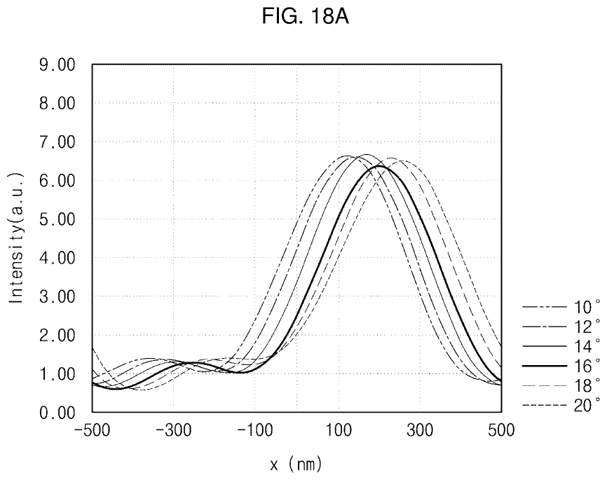

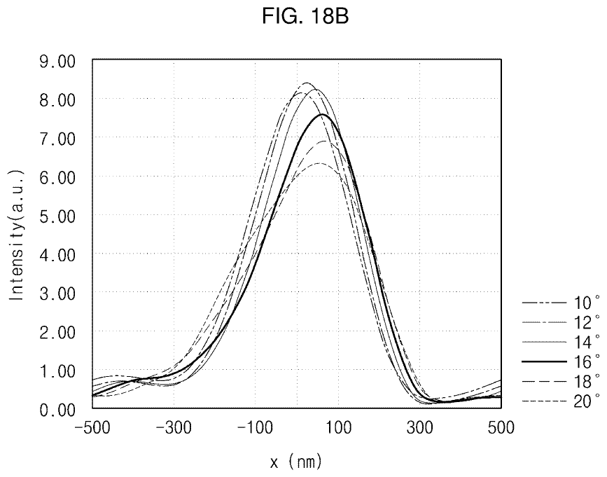

FIG. 17 is a diagram illustrating rigorous coupled-wave analysis (RCWA) images when an angle of incidence is changed to 10 degrees, 12 degrees, 14 degrees, 16 degrees, 18 degrees, and 20 degrees according to some example embodiments. In FIG. 17, experimental conditions except for an incident angle were the same as those of FIGS. 13A to 13C and 14A to 14C. FIGS. 18A and 18B are graphs, each illustrating the intensity of light depending on a position on a pixel in FIG. 17, and a position on an X-axis, a center of the pixel, corresponds to a point of 0 nm according to some example embodiments.

Referring to FIGS. 17, 18A, and 18B, it can be seen that when an asymmetrical microlens is used, an optical path is corrected to form a focus at a center of a pixel even if an angle of incidence is larger than that when a symmetrical microlens is used. The incident angle may be 20 degrees or more. In this case, in FIG. 17, it can be seen that a tail is formed in a direction on an image. This occurs when incident light having a significantly large angle of incidence is refracted by a microlens and does not travel to the focus. Accordingly, the angle corrected by the asymmetrical microlenses may be limited to less than 20 degrees.

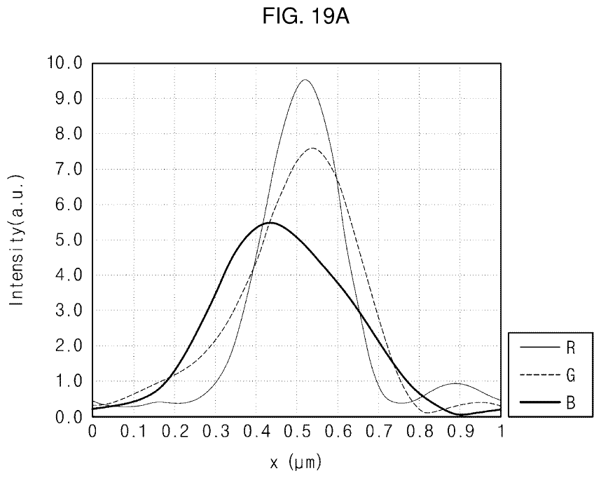

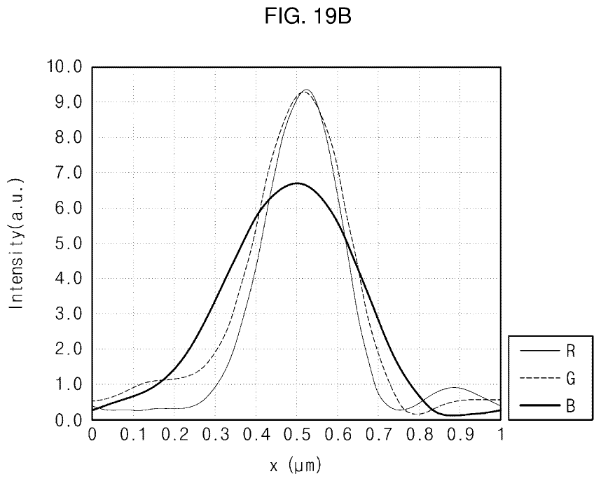

FIGS. 19A and 19B are graphs illustrating an optical path correction effect using an asymmetrical microlens when all conditions, other than a height, are the same according to some example embodiments. FIG. 19A is a graph illustrating intensity of light on a pixel when heights of first to third microlenses corresponding to first to third color filters are the same, and FIG. 19B is a graph illustrating intensity of light on a pixel when heights of first to third microlenses, in order from largest to smallest, correspond to the first to third color filters. In FIGS. 19A and 19B, the X-axis represents a distance from the top of a substrate to the bottom of the substrate, and an upper surface of the substrate is a point on the X-axis that corresponds to 0.5 μm.

Referring to FIGS. 19A and 19B, it can be seen that when the first to third microlenses are formed while having different heights to correct a focal position caused by chromatic aberration, the focal position moves toward the center of the pixel and the intensity of light is highest in the center of the pixel.

For example, light corresponding to a red color having a longest wavelength is generated deep at a position farthest from the center of the pixel. However, it can be seen that all red, green, and blue colors are almost accurately focused on a surface of a substrate using a microlens for correcting chromatic aberration. In addition, in the case of the blue color, a difference in the intensity of light is not large. However, in the case of the red color and the green color, the intensity of light was significantly increased when correction of chromatic aberration was performed, compared to when it was not performed.

As described above, in the case of an asymmetrical microlens, a refraction path of light may be changed such that the light travels to be more perpendicular to a focal plane. Accordingly, broadening at a focus may be reduced and the intensity of light may be increased to improve autofocusing performance. In addition, microlenses may be disposed in a color filter in consideration of chromatic aberration according to color filters to significantly improve light detection regardless of a color of light.

For example, a symmetrical microlens may be provided in a central portion of a pixel region having relatively low intensity of light incident to a side and an asymmetrical microlens may be provided in an edge portion having relatively high intensity of light incident to the side. In addition, different microlenses may be provided for each color in consideration of chromatic aberration. Thus, the intensity of light entering the entire pixel array may be fully detected to significantly improve a contrast during autofocusing.

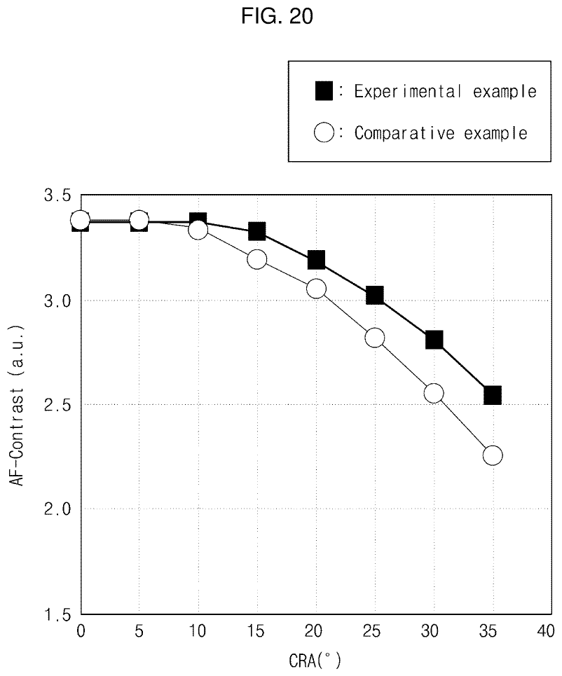

FIG. 20 is a contrast graph during autofocusing when an image sensor according to the related art is used as a comparative example and an image sensor according to some example embodiments is used as an experimental example. In FIG. 20, the image sensor according to the related art and the image sensor according to some example embodiments have the same configuration other than microlenses. In the image sensor according to the related art, the same symmetrical microlenses were used in an entire photo array. In the image sensor according to some example embodiments, a pixel region was divided into a first region and a second region (see FIG. 2A), and symmetrical microsensors were used in the first region and asymmetrical microsensors were used in the second region. In this case, the asymmetrical microsensors were manufactured in a structure having a correction effect of 5 degrees, compared to the symmetrical microsensors.

Referring to FIG. 20, it can be seen that a phenomenon, in which a constant during autofocusing decreases as a CRA increases, was reduced in the experimental example as compared to the comparative example.

In some example embodiments, including the example embodiments described above, a pixel region has been described as being divided into a central portion and an edge, for example, a first region in which symmetrical microlenses are disposed and a second region in which asymmetrical microlenses are disposed. However, example embodiments are not limited thereto. In some example embodiments, microlenses may be disposed such that asymmetry of the microlenses increases in a direction toward a side from a central portion of the pixel region.

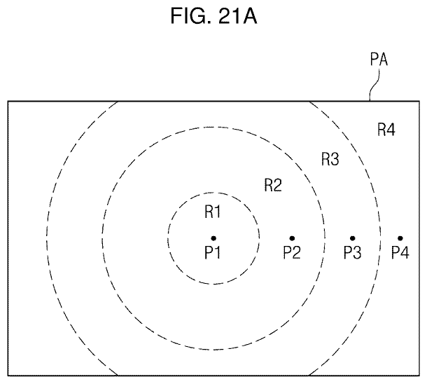

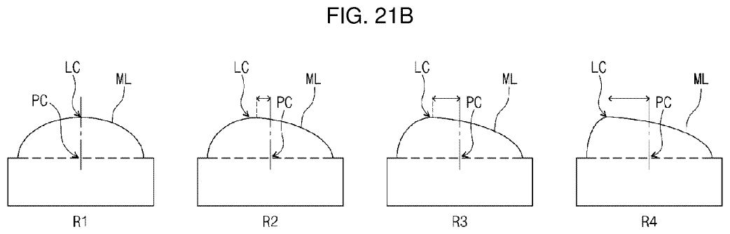

FIG. 21A is a diagram illustrating a pixel region in an image sensor according to some example embodiments, and FIG. 21B is a diagram sequentially illustrating shapes of microlenses P1, P2, P3, and P4 depending on positions of the pixel region according to some example embodiments.

Referring to FIGS. 21A and 21B, a pixel region PA may include a plurality of regions, for example, first to fourth regions R1, R2, R3, and R4 sequentially disposed in a direction from a central portion to an edge. The number of regions may be set in various ways. In some example embodiments, four regions are illustrated for ease of description.

In some example embodiments, microlenses ML may be disposed in each region to increase asymmetry in a direction toward an edge from a central portion of the pixel region PA, for example, in a direction toward the fourth region R4 from the first region R1. For example, a distance between an uppermost point of a microlens ML and a central portion PC of a single pixel may further increase within the pixel.

Accordingly, in consideration of a CRA of light entering the pixel region PA, the microlenses ML may be disposed such that asymmetry increases in a direction toward an edge from a central portion of the pixel region PA, resulting in improved autofocusing performance of pixels PX on a side of the edge.

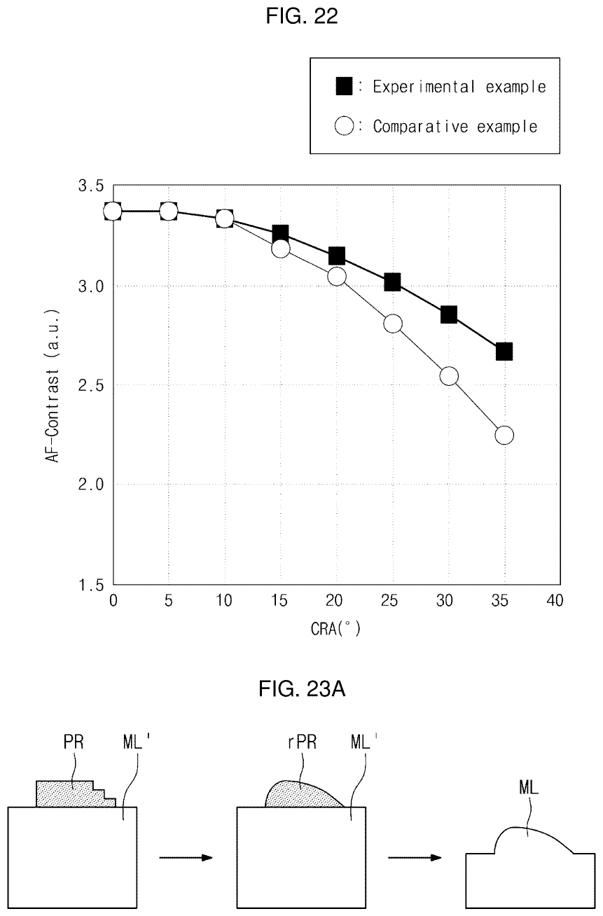

FIG. 22 is a contrast graph during autofocusing when an image sensor according to the related art is used as a comparative example and an image sensor according to some example embodiments is used as an experimental example.

In FIG. 22, the same conditions, other than microlenses, were applied to the image sensor according to the related art and the image sensor according to some example embodiments. In the image sensor according to the related art, the same symmetrical microlenses were used in the entire photo array. In the image sensor according to some example embodiments, asymmetrical lenses, increasing a correction angle in a direction toward an edge from a central portion, were used. In this case, a correction angle for the asymmetrical microlenses ML was set such that a corrected angle is less than or equal to 20% of a correction angle of the symmetrical microlens. For example, a shape of the microlens ML was prepared such that when a first angle (see FIG. 12A) of the symmetrical microlens ML is 10 degrees, a second angle (see FIG. 12B) of the asymmetrical microlenses ML is 8 degrees.

Referring to FIG. 22, it can be seen that a phenomenon in which a constant during autofocusing decreases as a CRA increases, was reduced in the experimental example as compared to the comparative example. In addition, an autofocusing contrast may be significantly increased as compared to the above-described example embodiments in which the pixel region PA is divided into two regions.

The image sensor having the above configuration may improve autofocusing performance by correcting a phase difference of light, passing through a microlens, when autofocusing using a phase difference is implemented. For example, a microlens having an asymmetrical structure may be formed to compensate for a phase of incident light entering a microlens and may have different heights, different radii of curvature, or the like, to compensate for chromatic aberration depending on each color. In this case, the autofocusing performance may be improved by compensating for a phase difference of light, and sensitivity to each color may also be improved.

A microlens according to some example embodiments may be easily manufactured by adding a simple additional process to a process of manufacturing a symmetrical microlens.

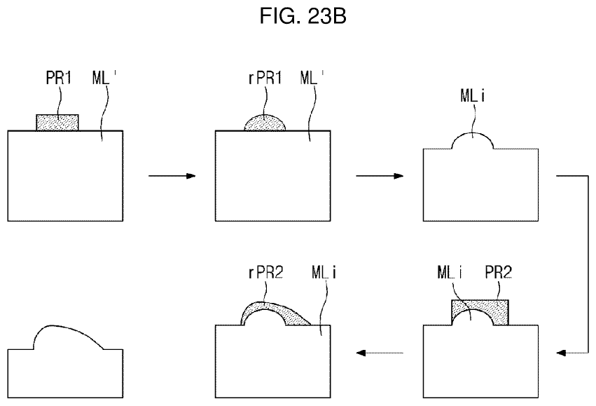

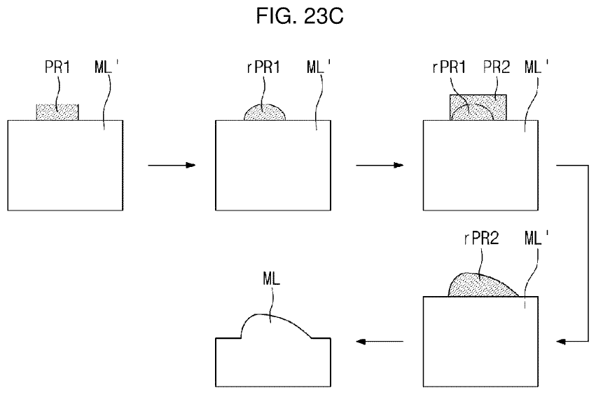

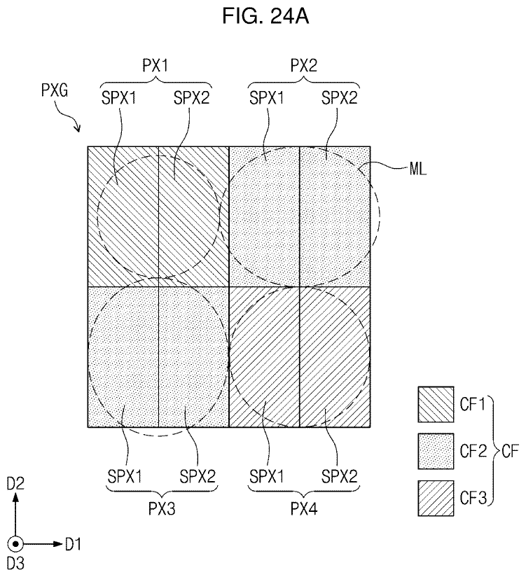

FIGS. 23A, 23B, and 23C are diagrams sequentially illustrating a method of manufacturing an asymmetrical microlens according to some example embodiments. In the drawings, other components such as a lower substrate are omitted for ease of description.

Referring to FIG. 23A, a microlens material ML′ such as a transparent polymer may be formed as a planarization layer on a substrate on which color filters are formed, and a photoresist pattern PR may be disposed in a region in which a microlens is to be formed. The microlens material ML′ may be provided on color filters, not illustrated, to planarize unevenness of a structure that may be formed by a color filter, and may have transmittance in a visible light wavelength and a refractive index of 1.5 to 2.

The photoresist pattern PR may be formed to have an asymmetric staircase shape. The staircase shape of the photoresist pattern may be formed to correspond to a shape of a microlens to be formed, and may be formed such that an uppermost staircase of the photoresist pattern is formed in a position corresponding to an uppermost portion of the microlens. To this end, the photoresist pattern may be formed by forming a plurality of apertures, in which a photoresist is not provided, in a specific region in a dummy type, or controlling the intensity of light, provided to a photoresist, using a mask having a plurality of regions (for example, at least two regions) during exposure.

Next, the photoresist pattern PR may be reflowed. The reflowed photoresist pattern rPR may have an asymmetrical shape. Finally, an etch-back process may be performed using the reflowed photoresist pattern rPR as a mask to form an asymmetrical microlens ML.

Referring to FIG. 23B, a microlens material ML′ such as a transparent polymer may be formed as a planarization layer on a substrate on which color filters are formed, and a first photoresist pattern PR1 may be disposed in a region in which a microlens is to be formed. The microlens material ML′ may be provided on color filters, not illustrated, to planarize unevenness of a structure that may be formed by a color filter, and may have transmittance in a visible light wavelength and a refractive index of 1.5 to 2.

Then, the first photoresist pattern PR1 may be reflowed, and an etch-back process may be performed using the reflowed first photoresist pattern rPR1 as a mask to form a symmetrical microlens MLi. Then, a second photoresist pattern PR2 may be disposed on the symmetrical microlenses MLi. In this case, the second photoresist pattern PR2 may be patterned to have an asymmetrical shape with respect to a center of the preformed symmetrical microlenses MLi. For example, the center of the preformed symmetrical microlenses MLi and the center of the pattern PR2 of the second photoresist do not match each other. Next, the second photoresist pattern PR2 may be reflowed. Finally, an etch-back process is performed using the reflowed second photoresist pattern rPR2 as a mask to form an asymmetrical microlens ML.

Referring to FIG. 23C, a microlens material ML′ such as a transparent polymer may be formed as a planarization layer on a substrate on which color filters are formed, and a first photoresist pattern PR1 may be disposed in a region in which a microlens is to be formed. Then, the first photoresist pattern PR1 may be reflowed. Then, a second photoresist pattern PR2 may be formed on the reflowed first photoresist pattern rPR1, and the second photoresist pattern PR2 may be reflowed. A center of the second photoresist pattern PR2 does not match the center of the preformed reflowed first photoresist pattern rPR1. Accordingly, when the second photoresist pattern PR2 is reflowed, the reflowed second photoresist pattern rPR2 may have an asymmetrical shape. Next, an etch-back process may be performed using the reflowed second photoresist pattern rPR2 as a mask to form an asymmetrical microlens ML.

In some example embodiments, the first and second photoresists, used when the microlenses are formed, may be selected from photosensitive materials having an etching rate, substantially similar to an etching rate of a material of the microlenses. In some example embodiments, the symmetrical microlenses and the asymmetrical microlenses may be formed by the above-described method, and a layout of the first and second photoresists may be changed to correspond to different colors for each pixel. As a result, microlenses having different shapes depending on colors may be formed.

According to some example embodiments, the image sensor having the above configuration may be modified in various forms within the scope of the concept of the present inventive concepts.

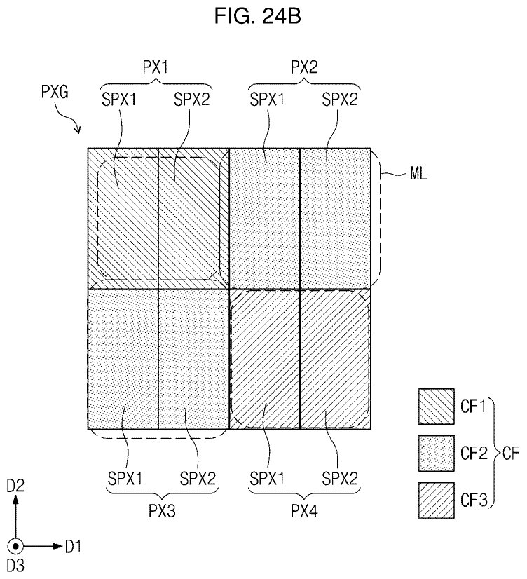

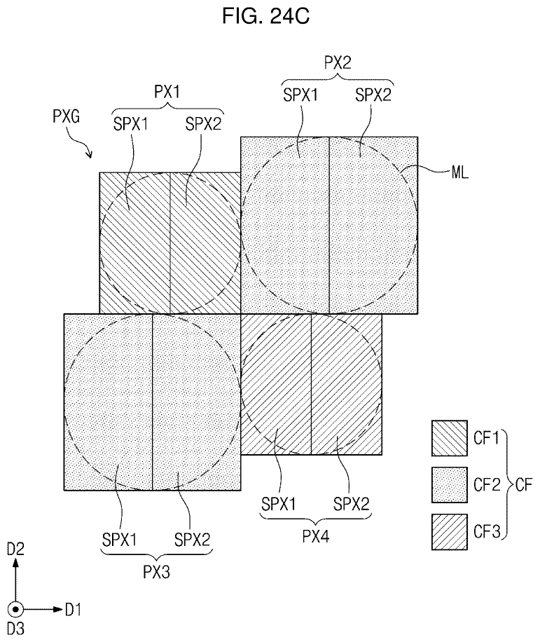

FIGS. 24A, 24B, and 24C are diagrams illustrating a single pixel group in an image sensor according to some example embodiments.

Referring to FIGS. 24A to 24C, image sensors may be manufactured in different forms for each color, taking into account an absorption rate depending on a wavelength of a substrate in an image sensor.

As illustrated in FIGS. 24A and 24B, the image sensor according to some example embodiments may include microlenses ML having the same pixel region but having different sizes for each color (for example, microlenses ML having different aperture ratios). In some example embodiments, as illustrated in FIG. 24B, the image sensor according to some example embodiments may have different pixel regions and microlenses of different sizes corresponding thereto. As illustrated in FIGS. 24A and 24B, the shape of the microlenses corresponding to each pixel may be provided as various shapes such as a circle, an ellipse, or a polygon (e.g., a rectangle) when viewed in plan view.

In some example embodiments, when first to fourth pixels PX1, PX2, PX3, and PX4 are arranged in a 2×2 matrix, the second and third pixels PX2 and PX3 may be extended to a larger microlens ML or a larger area than another pixel PX. Simultaneously, the first pixel PX1 and/or the fourth pixel PX4 may be shrunk to have a smaller microlens ML or a smaller area than the second and third pixels PX2 and PX3. The first pixel PX1 may correspond to a blue color as a first color filter CF1, the second pixel PX2 may correspond to a green color as a second color filter CF2, the third pixel PX3 may correspond to the green color as the second color filter CF2, and the fourth pixel PX4 may correspond to a red color as a third color filter CF3. Such a change in colors may allow a photoelectric conversion element PD to more easily convert light of a specific color. When an area of each microlens ML is decreased or increased, a focus of each microlens may be set such that it does not deviate as far as possible from the center of a corresponding pixel and/or pixels.

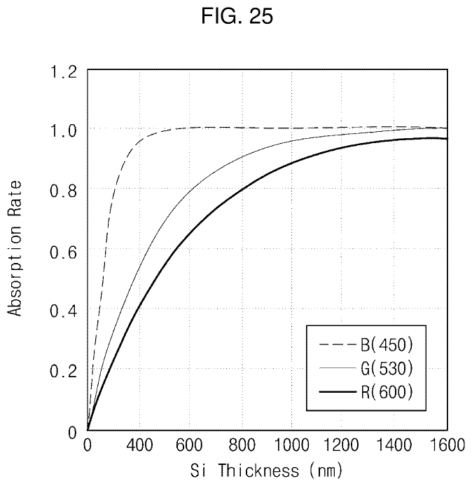

An actual semiconductor substrate, for example, a silicon-based substrate, has a light absorptivity varying depending on a wavelength, and FIG. 25 is a graph illustrating relative absorptivity of light by color depending on a thickness when the substrate is a silicon-based substrate according to some example embodiments. FIG. 25 illustrates absorptivity of blue (B, 450 nm), green (G, 530 nm), and red (R, 600 nm) lights depending on a thickness of the silicon-based substrate.

As illustrated in FIG. 25, in the silicon-based substrate, light absorptivity decreased in the order of blue, green, and red. In the image sensor, sensitivity to a green color is important due to human visual characteristics in which a green color is sensitively distinguished. To compensate for the sensitivity of green color, as illustrated in FIG. 24A or 24B, an area of the first pixel PX1 corresponding to blue, having a high absorptivity, may be relatively decreased, areas of the second pixel PX2 and the third pixel PX3 corresponding to green, having a relatively low absorptivity, may be relatively increased, an area on a plane of a microlens of the first pixel PX1 corresponding to blue, having a high absorptivity, may be relatively decreased, and areas of microlenses of the second pixel PX2 and the third pixel PX3 corresponding to green, having a relatively low absorptivity, may be relatively increased.

In some example embodiments, only the areas of the second and third pixels PX2 and PX3 corresponding to green may be increased, but example embodiments are not limited thereto. In some example embodiments, an area of the fourth pixel PX4 corresponding to red may be increased.

In the image sensor according to some example embodiments, the arrangement, connection relationship, and driving method of the pixels PX may be changed in various forms.

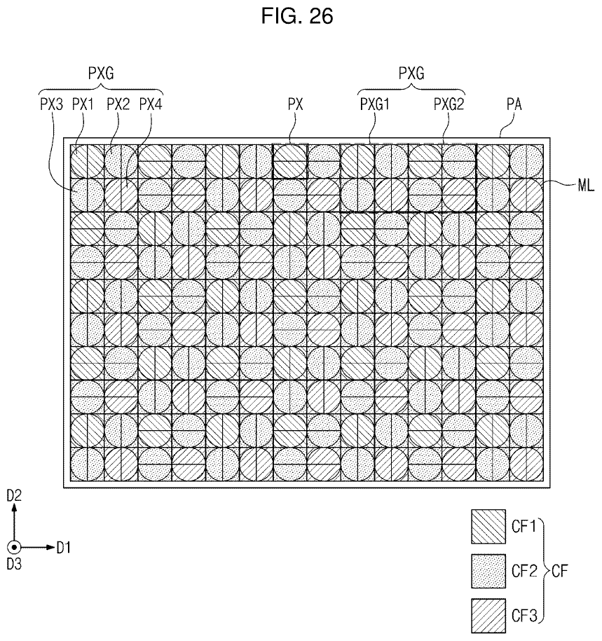

FIG. 26 is a diagram illustrating a pixel array of an image sensor according to some example embodiments.

Referring to FIG. 26, a pixel array may be provided in a pixel region PA. The pixel array may include a plurality of pixel groups PXG.

According to some example embodiments, the pixel groups PXG may include first pixel groups PXG1 and second pixel groups PXG2. The first pixel groups PXG1 and the second pixel group PXG2 may be alternately arranged in a matrix in a first direction D1 and a second direction D2.

The first pixel groups PXG1 and the second pixel groups PXG2 have the same or substantially the same structure, but subpixels PX included in each of the pixels PX may have different arrangement directions. In the first pixel group PXG1, the first and second subpixels SPX1 and SPX2 in the first to fourth pixels PX1, PX2, PX3, and PX4 may be sequentially disposed in the first direction D1. In the second pixel group PXG2, first and second subpixels SPX1 and SPX2 in the first to fourth pixels PX1, PX2, PX3, and PX4 may be sequentially disposed in a direction, different from that of the first pixel group PXG1, for example, in a second direction D2.

According to some example embodiments, some of the first and second subpixels SPX1 and SPX2 may be arranged in the first direction D1, while some of the first and second subpixels SPX1 and SPX2 may be arranged in the second direction D2. Accordingly, autofocusing performance may be improved for both light incident in a horizontal direction and light incident in a vertical direction when viewed in plan view.

In some example embodiments, the first and second subpixels SPX1 and SPX2 are illustrated as being divided and arranged in the first direction D1 or the second direction D2 within a single pixel PX. However, example embodiments are not limited thereto, and the first and second subpixels SPX1 and SPX2 may be divided and arranged in directions other than the first direction D1 or the second direction D2. Light may be incident on a microlens of the image sensor in various directions, rather than a single direction. The first and second subpixels SPX1 and SPX2 may be arranged to be different from the above arrangement, and thus lights incident in various directions may be efficiently detected.

In some example embodiments, the first pixel groups PXG1 and the second pixel groups PXG2 are illustrated as being alternately arranged, but example embodiments are not limited thereto. The arrangement of the first pixel groups PXG1 and the second pixel groups PXG2 may be changed in various forms. For example, the first pixel groups PXG1 may be disposed in even rows, and the second pixel groups PXG2 may be disposed in odd rows.

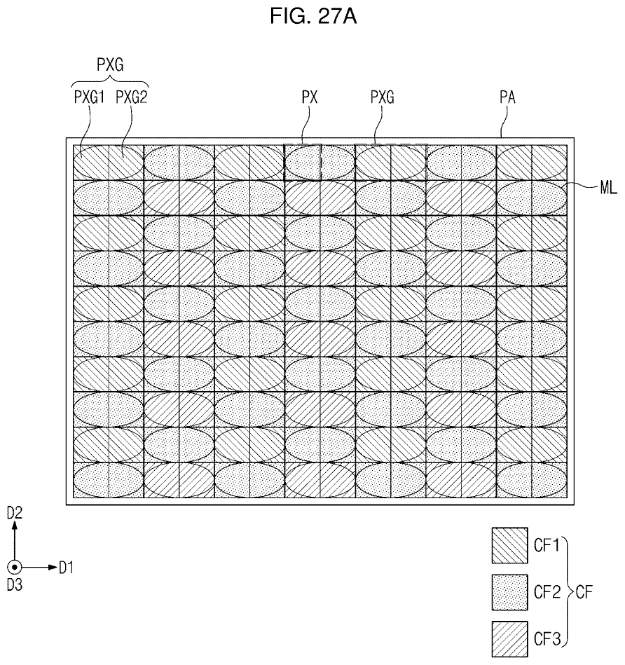

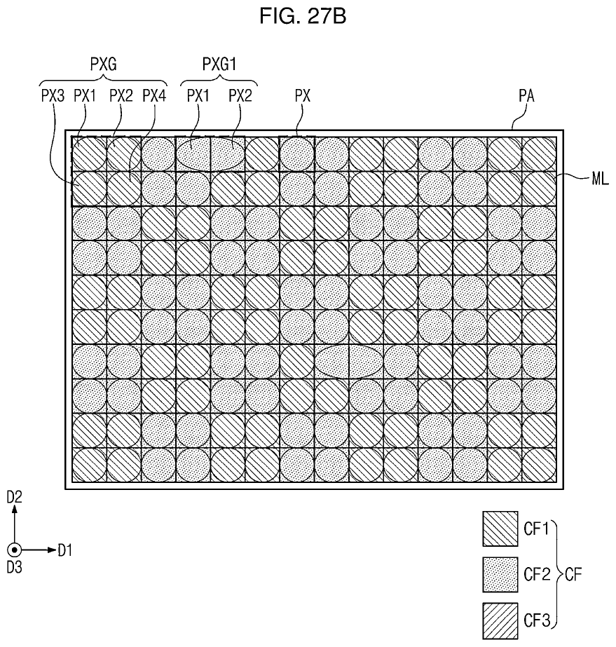

FIGS. 27A and 27B are diagrams illustrating pixel arrays of an image sensor according to some example embodiments.

Referring to FIGS. 27A and 27B, a pixel array may be provided in the pixel region PA. The pixel array may include a plurality of pixel groups PXG. At least a portion of the plurality of pixel groups PXG may include first and second pixels PX1 and PX2 arranged in a 1×2 matrix for autofocusing.

Referring to FIG. 27A, a plurality of pixel groups PXG having the same shape may be provided in the pixel region PA. Among reference colors, a single color may be assigned to each pixel group PXG. First and second pixels PX1 and PX2 in each pixel group PXG may have the single assigned color, among the reference colors. For example, a blue color may be assigned to a single pixel group PXG. In this case, both the first and second pixels PX1 and PX2 may have a blue color filter.

Each of the pixel groups PXG may have a single color. When a plurality of pixel groups PXG are arranged, they may be formed overall in a Bayer pattern. For example, when four pixel groups PXG are arranged to have a 2×2 matrix shape, two pixel groups PXG in a first row may have blue and green colors, respectively, and two pixel groups PXG in a second row may have green and red colors, respectively.

In some example embodiments, a single pixel group PXG including the first and second pixels PX1 and PX2 may be provided with a single microlens ML. For example, two pixels PX adjacent to each other in a first direction D1 may constitute a single pixel group PXG, and the first and second pixels PX1 and PX2 may share the single microlens ML. In FIG. 27, the first and second pixels PX1 and PX2 are illustrated as being disposed adjacent to each other in the first direction D1 and the microlens ML is illustrated as corresponding to two pixels PX adjacent to each other in the first direction D1. However, example embodiments are not limited thereto, at least a portion of the first and second pixels PX1 and PX2 may be disposed adjacent to each other in a second direction D2, and the microlens ML may correspond to two pixels PX adjacent to each other in the second direction D2.

Referring to FIG. 27B, a plurality of pixel groups having the same shape may be provided in a pixel region PA. The pixel groups may be arranged in different forms. As illustrated in FIG. 27B, a pixel group may include first pixel groups PXG1, arranged in a 1×2 matrix, and second pixel groups PXG2 arranged in a 2×2 matrix. Some pixels, included in the first and second pixel groups PXG1 and PXG2, may be shared as illustrated in the drawing.

Among reference colors, a single reference color may be assigned to each of the pixel groups PXG1 and PXG2. For example, the first and second pixels PX1 and PX2 in the first pixel group PXG1 may have a single assigned reference color. The first to fourth pixels PX1, PX2, PX3, and PX4 in the second pixel group PXG2 may also have the single assigned reference color. For example, a green color may be assigned to the first pixel group PXG1. In this case, both the first and second pixels PX1 and PX2 may include a green color filter. Blue color may be assigned to one second pixel group PXG2, and in this case, blue color may be assigned to all of the first to fourth pixels PX1, PX2, PX3, and PX4. As illustrated in FIG. 27B, when one of the pixels of the first pixel group PXG1 (for example, the second pixel PX2) and one of the adjacent pixels of the second pixel group PXG1 (for example, the second pixel PX1) are shared, the shared pixel may have the same color as the remaining pixel (for example, the first pixel PX1) of the first pixel group PXG1.

In some example embodiments, the first and second pixels PX1 and PX2 of each first pixel group PXG1 may share a microlens ML with each other, whereas the first to fourth pixels PX1, PX2, PX3, and PX4 of each second pixel group PXG2 may not share a microlens and may each have a microlens ML.

As described above, the pixel array may include pixel groups, each including two pixels PX1 and PX2 sharing a microlens ML. All of the pixels may be two pixels PX1 and PX2 sharing a microlens, or a portion of the pixels may be two pixels PX1 and PX2 sharing microlens. In the case of some example embodiments, a single pixel group may include first and second pixels PX1 and PX2 different from each other for autofocusing, and a photoelectric conversion signal of a photoelectric conversion element included in each of the pixels PX may be independently read. Autofocusing may be performed by detecting a phase difference using a disposition relationship between different photoelectric conversion elements PD included in the respective pixels.

Such phase difference detection may be performed for each direction in which photoelectric conversion elements in the first and second pixels PX1 and PX2 are disposed. In some example embodiments, when the first and second pixels PX1 and PX2 are disposed to be different in a first direction D1 and a second direction D2, a phase difference may be detected in both a horizontal direction and a vertical direction because the first and second pixels PX1 and PX2 are arranged in the first direction D1 and the second direction D2.

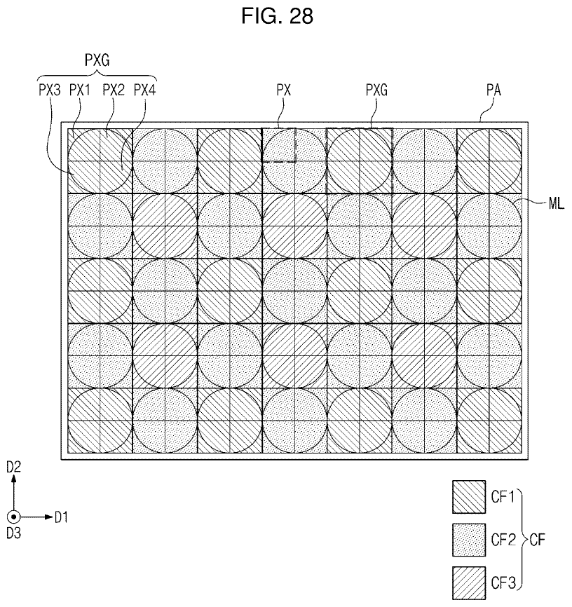

FIG. 28 is a diagram illustrating a pixel array of an image sensor according to some example embodiments.

Referring to FIG. 28, a pixel array may be provided in a pixel region PA. The pixel array may include a plurality of pixel groups PXG. Each of the pixel groups PXG may include first to fourth pixels PX1, PX2, PX3, and PX4 arranged in a 2×2 matrix.

Among reference colors, a single reference color may be assigned to each pixel group PXG, and first to fourth pixels PX1, PX2, PX3, and PX4 in each pixel group PXG may have the assigned single color. For example, a green color may be assigned to a single pixel group PXG. In this case, each of the first to fourth pixels PX1, PX2, PX3, and PX4 may have a green color filter.

Each of the pixel groups PXG may have a single color. When a plurality of pixel groups PXG are arranged, they may be formed overall in a Bayer pattern. For example, when four pixel groups PXG are arranged to have a 2×2 matrix form, two pixel groups PXG in a first row may have blue and green colors, respectively, and two pixel groups PXG in a second row may have green and red colors, respectively.

In some example embodiments, a single microlens ML may be provided in a single pixel group PXG including the first to fourth pixels PX1, PX2, PX3, and PX4. For example, the first to fourth pixels PX1, PX2, PX3, and PX4 in the single pixel group PXG may share a single microlens ML.

In some example embodiments, a single pixel group PXG may include first to fourth pixels PX1, PX2, PX3, and PX4 different from each other, and a photoelectric conversion signal of a photoelectric conversion element included in each of the pixels PX may be independently read. Autofocusing may be performed by detecting a phase difference using a disposition relationship between different photoelectric conversion elements PD included in the respective pixels. Such phase difference detection may be performed for each direction in which photoelectric conversion elements in the first to fourth pixels PX1, PX2, PX3, and PX4 are disposed. In some example embodiments, a phase difference may be detected in both a horizontal direction and a vertical direction because the first to fourth pixels PX1, PX2, PX3, and PX4 are arranged in the first direction D1 and the second direction D2.

Although not described additionally, in some example embodiments, the pixel array may include a plurality of pixel groups PXG, and each of the pixel groups PXG may include first to ninth pixels arranged in a 3×3 matrix.

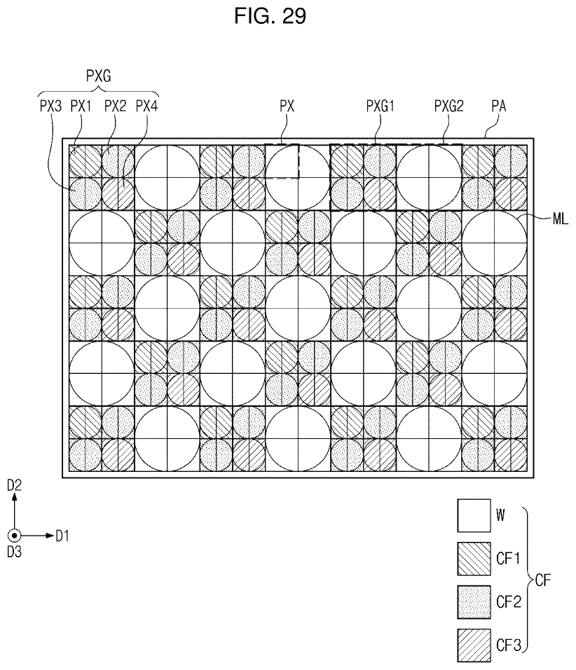

FIG. 29 is a diagram illustrating a pixel array of an image sensor according to some example embodiments.

Referring to FIG. 29, a pixel array may include a plurality of pixel groups PXG. The plurality of pixel groups PXG may include first and second pixel groups PXG1 and PXG2. Each of the first pixel groups PXG1 may include first to fourth pixels PX1, PX2, PX3, and PX4 having different colors, and each of the first to fourth pixels PX1, PX2, PX3 and PX4 may be provided with microlenses ML. Each of the second pixel groups PXG2 may include first to fourth pixels PX1, PX2, PX3, and PX4 having the same color, and each of the first to fourth pixels PX1, PX2, PX3, and PX4 may be provided with a single microlens ML. A color, other than the first to third colors, may be assigned to the second pixel group PXG2. For example, a white color may be assigned to the second pixel group PXG2.

The second pixel group PXG2 of the pixel array may be provided with a white pixel PX to significantly increase light entering a photoelectric conversion element PD. Thus, sensitivity of an image sensor may be improved. In addition, the first pixel group PXG1 may be provided to implement autofocusing as well as image sensing.

As set forth above, according to some example embodiments, a microlens may be formed to have an asymmetrical shape, and thus a phase difference may be corrected. In addition, by providing a structure in which phase correction is optimized depending on a color, sensitivity of an image sensor may be improved.

According to some example embodiments, a phase may be corrected based on conditions of incident light to provide an image sensor having an improved autofocusing function.

As described herein, any devices, systems, modules, portions, units, controllers, circuits, and/or portions thereof according to any of the example embodiments, and/or any portions thereof (including, without limitation, the image sensor 1000, the pixel array 1, the row decoder 2, the row driver 3, the column decoder 4, the timing generator 5, the correlated double sampler 6, the analog-to-digital converter 7, the input/output buffer 8, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

While some example embodiments have been shown and described above, it will be apparent to those skilled in the art that modifications and variations could be made without departing from the scope of the present inventive concepts as defined by the appended claims.

What is claimed is:

1. An image sensor, comprising:
a pixel array in which a plurality of pixels having photoelectric conversion elements are arranged in a matrix in a first direction and a second direction intersecting the first direction;
color filters corresponding to the plurality of pixels, each color filter configured to selectively transmit light of a particular wavelength band, at least some of the color filters configured to selectively transmit light of at least two different wavelength bands from each other; and
microlenses on the color filters, each microlens of the microlenses at least partially overlapping a separate corresponding color filter of the color filters in a third direction that is perpendicular to the first and second directions, the microlenses configured to condense lights incident on the plurality of pixels and entering the photoelectric conversion elements through the color filters,
wherein at least some microlenses of the microlenses have different shapes depending on respective wavelength bands that respective corresponding color filters at least partially overlapping with the at least some microlenses are configured to selectively transmit, such that the at least some microlenses are configured to compensate for chromatic aberration between the lights passing through the respective corresponding color filters, and
wherein the pixel array is in a pixel region, and a distance between an uppermost point of each respective microlens of the microlenses and a center of a corresponding pixel of the plurality of pixels at least partially overlapping the respective microlens in the third direction increases in a direction toward an edge portion of the pixel region from a central portion of the pixel region.

2. The image sensor of claim 1, wherein
at least one microlens of the microlenses, when viewed in a cross-section passing through a center of a respective corresponding pixel and taken in a direction parallel to the first direction, have an asymmetric shape with respect to a line passing through the center of the corresponding pixel.

3. The image sensor of claim 2, wherein
the uppermost point of each respective microlens of the microlenses is a point of the respective microlens protruding furthest in the third direction, the uppermost point of the respective microlens is spaced apart from the center of the corresponding pixel on a plane.

4. The image sensor of claim 3, wherein
the color filters comprise first to third color filters configured to transmit different wavelength bands of light from each other, and
the microlenses comprise first to third microlenses, respectively on the first to third color filters, the first to third microlenses having different shapes from each other based on the different, respective wavelength bands of light that the first to third color filters are respectively configured to selectively transmit.

5. The image sensor of claim 4, wherein
the first to third color filters are configured to selectively transmit sequentially longer wavelengths, such that
the second color filter is configured to selectively transmit a longer wavelength than the first color filter, and
the third color filter is configured to selectively transmit a longer wavelength than the second color filter, and
heights of respective uppermost points of the first to third microlenses in the third direction are sequentially increased, such that
a height of an uppermost point of the second microlens is greater than a height of an uppermost point of the first microlens, and
a height of an uppermost point of the third microlens is greater than the height of the uppermost point of the second microlens.

6. The image sensor of claim 5, wherein
the first color filter is a blue color filter,
the second color filter is a green color filter, and
the third color filter is a red color filter.

7. The image sensor of claim 6, wherein
an area of a pixel corresponding to the second color filter is larger than an area of a separate pixel corresponding to the first color filter or the third color filter.

8. The image sensor of claim 6, wherein
a size of the second microlens corresponding to the second color filter is larger than a size of either the first microlens corresponding to the first color filter or the third microlens corresponding to the third color filter.

9. The image sensor of claim 5, wherein
in a cross-section passing through respective uppermost points of the first to third microlenses and taken in the second direction, respective radii of curvature at the respective uppermost points of the first to third microlenses increase in an order from the first microlens to the third microlens, such that
the second microlens has a greater radius of curvature than the first microlens, and
the third microlens has a greater radius of curvature than the second microlens.

10. The image sensor of claim 1, wherein
each of the microlenses has a shape of a circle, an ellipse, and/or a polygon, when viewed in plan view.

11. The image sensor of claim 1, wherein
at least a portion of a first region, in which each respective microlens of the microlenses is located, overlaps a second region in which a pixel of the plurality of pixels corresponding to the respective microlens is located, when viewed in plan view.

12. The image sensor of claim 11, wherein
the first region and the second region are offset by a first distance in the first direction, and the first distance increases in the direction toward the edge portion of the pixel region from the central portion of the pixel region.

13. The image sensor of claim 1, wherein
at least some of the pixels each comprise a first subpixel and a second subpixel, sequentially arranged in the first direction and/or the second direction.

14. The image sensor of claim 13, wherein
the first subpixel and the second subpixel share a single microlens.

15. The image sensor of claim 1, wherein
the pixel array comprises a plurality of pixel groups, and each pixel group of the plurality of pixel groups comprises first to fourth pixels, the first to fourth pixels arranged in a 2×2 matrix.

16. The image sensor of claim 15, wherein
the color filters comprises first to third color filters configured to selectively transmit different wavelength bands of light, and
the first to fourth pixels correspond to one of the first to third color filters.

17. The image sensor of claim 16, wherein
the first to third color filters are configured to transmit wavelength bands of light corresponding to blue, green, and red colors, respectively,
the first pixel corresponds to the first color filter,
the second and third pixels correspond to the second color filter, and
the fourth pixel corresponds to the third color filter.

18. The image sensor of claim 15, wherein
the microlenses correspond to each pixel group of the plurality of pixel groups, and
the first to fourth pixels in each pixel group of the plurality of pixel groups share a single corresponding microlens.

19. An image senor, comprising:
a pixel array in which a plurality of pixels having photoelectric conversion elements are arranged in a matrix in a first direction and a second direction intersecting the first direction;
first to third color filters corresponding to the plurality of pixels, the first to third color filters configured to transmit light of sequentially longer wavelengths, such that
the second color filter is configured to selectively transmit a longer wavelength than the first color filter, and
the third color filter is configured to selectively transmit a longer wavelength than the second color filter; and
first to third microlenses, respectively on the first to third color filters, the first to third microlenses configured to condense lights incident on the pixels through the first to third color filters,
wherein each microlens of the first to third microlenses, when viewed in a cross-section passing through a center of a corresponding pixel and taken in a direction parallel to the first direction, have an asymmetric shape with respect to a line passing through the center of the corresponding pixel,
wherein each microlens of the first to third microlenses has a respective uppermost point that is a point of the microlens protruding furthest in a third direction perpendicular to the first and second directions, and heights of respective uppermost points of the first to third microlenses in the third direction increase sequentially, such that
a height of an uppermost point of the second microlens is greater than a height of an uppermost point of the first microlens, and
a height of an uppermost point of the third microlens is greater than the height of the uppermost point of the second microlens, and
wherein the pixel array is in a pixel region, and a distance between the respective uppermost point of each microlens of the first to third microlenses and a center of a respective pixel corresponding to the microlens increases in an outward direction toward an edge portion of the pixel region from a central portion of the pixel region.

20. A method of manufacturing an image sensor, the image sensor comprising a pixel array in which a plurality of pixels having photoelectric conversion elements are arranged in a matrix in a first direction and a second direction intersecting the first direction, color filters provided to correspond to the pixels and having at least two types of different colors, and microlenses provided on the color filters to condense lights incident on the pixels through the color filters, the method comprising:
forming a planarization layer on the color filters, the planarization formed of a microlens material;
providing a photoresist on the planarization layer, the photoresist having an asymmetrical shape;
reflowing the photoresist; and
etching the planarization layer using the reflowed photoresist as a mask.
